(19) United States
(12) Patent Application Publication
(10) Pub. No.: US 2023/0322546 A1
(43) Pub. Date: Oct. 12, 2023

(54) MEMS with cover drive and method of operating the same

(71) Applicant: Fraunhofer-Gesellschaft zur Förderung der angewandten Forschung e.V., München (DE)

(72) Inventors: Sergiu LANGA, Dresden (DE); Bert KAISER, Dresden (DE); Anton MELNIKOV, Dresden (DE); Jorge Mario MONSALVE GUARACAO, Dresden (DE)

(21) Appl. No.: 18/328,129

(22) Filed: Jun. 2, 2023

Related U.S. Application Data
(63) Continuation of application No. PCT/EP2020/084506, filed on Dec. 3, 2020.

(51) Int. Cl. B81C 1/00; B81B 3/00

(52) U.S. Cl. CPC B81B 3/0021; B81C 1/00198; B81B 2201/0257; B81B 2203/0315; B81B 2203/033; B81B 2203/04; B81B 2203/053; B81C 2201/013; B81C 2203/032; B81C 2203/035

(57) ABSTRACT

A MEMS device includes a layer stack having a plurality of MEMS layers arranged along a layer stack direction. The MEMS device includes a movable element formed in a first MEMS layer and arranged between a second MEMS layer and a third MEMS layer of the layer stack. A driving unit is further provided, comprising a first drive structure mechanically firmly connected to the movable element and a second drive structure mechanically firmly connected to the second MEMS layer. The driving unit is configured to generate on the movable member a drive force perpendicular to the layer stack direction, and the drive force is configured to deflect the movable member.

### CROSS-REFERENCE TO RELATED APPLICATION

This application is a continuation of copending International Application No. PCT/EP2020/084506, filed Dec. 03, 2020, which is incorporated herein by reference in its entirety.

### TECHNICAL FIELD

The present invention relates to a MEMS device and to a method of operating the same. More particularly, the present invention relates to a MEMS having a cover drive for driving a movable element in-plane.

### BACKGROUND OF THE INVENTION

MEMS transducers formed from a substrate and having limited geometric dimensions or aspect ratios due to the restricted aspect ratio, for example the Bosch method, are known. If the volume of a MEMS device is to be increased, this is possible, for example, by etching more deeply. At the same time, however, it is not possible to realize a small electrode distance between adjacent electrodes, since the same is also increased due to the etching method. Thus, it is at least difficult to form a transducer that, on the one hand, can interact with a large volume of the surrounding fluid and, on the other hand, can apply the necessary force or comprises correspondingly small electrode distances.

Therefore, there is a need for MEMS transducers that have a large aspect ratio to be able to move large fluid volumes while realizing small electrode distances.

### SUMMARY

According to an embodiment, a MEMS device may have: a layer stack having a plurality of MEMS layers arranged along a layer stack direction; a movable element formed in a first MEMS layer; the moveable element arranged between a second MEMS layer and a third MEMS layer of the layer stack, a driving unit having a first drive structure mechanically firmly connected to the movable element and a second drive structure mechanically firmly connected to the second MEMS layer; wherein the driving unit is configured to generate on the movable element a drive force perpendicular to the layer stack direction, and the drive force is configured to deflect the movable element.

According to another embodiment, a method of operating a MEMS device may have the steps of: controlling two drive structures arranged along a layer stack direction along which a multitude of MEMS layers of the MEMS device are arranged, and generating a drive force at a movable element of the MEMS device perpendicular to the layer stack direction through the controlling so as to deflect the MEMS device.

A core idea of the present invention is to have recognized that an in-plane actuation of a movable element can also be based on an electrode arrangement that is arranged perpendicularly to the direction of movement, which makes it possible to extract large movable elements, for example by means of etching, and, at the same time, to allow small gap distances perpendicular to the direction of movement, since these gap distances can be independent of the etching process used.

According to an embodiment, a MEMS device includes a layer stack having a plurality of MEMS layers arranged along a layer stack direction. Further, a movable element formed in a first MEMS layer and arranged between a second MEMS layer and a third MEMS layer of the layer stack is provided. The MEMS device includes a driving unit having a first drive structure mechanically firmly connected to the movable element and a second drive structure mechanically firmly connected to the second MEMS layer, which allows forces to be applied between the two drive structures. The driving unit is configured to generate on the movable element a drive force perpendicular to the layer stack direction, wherein the drive force is configured to deflect the movable element, in particular with a component perpendicular to the layer stack direction, which may include a rotational movement, a torsional movement and/or a translational movement.

According to an embodiment, the first drive structure and the second drive structure are spaced apart by a gap and arranged opposite to each other. A dimension of the gap along the layer stack direction is adjusted by, for example, a bonding process. Bonding processes enable small gap distances, so that high forces can be generated, for example, using electrostatic or electrodynamic drive forces.

According to an embodiment, the movable element is configured such that it comprises a plurality of layers bonded by a bonding process. This makes it possible to obtain large movable elements and thus high aspect ratios so that a high level of fluid can be moved with the movable element.

According to an embodiment, the second drive structure is a structured electrode structure having at least one first electrode element and one second electrode element electrically insulated therefrom. The MEMS device is configured to apply a first electrical potential to the first electrode element and a different second electrical potential to the second electrode element. The MEMS device is further configured to apply a third electrical potential to the first drive structure to generate the drive force in cooperation of the third electrical potential and the first electrical potential or the second electrical potential. This allows, for example, a bidirectional and possibly linear deflection of the movable element in terms of a back-and-forth movement, which is advantageous.

According to an embodiment, the first electrode element and the second electrode element are electrically insulated from each other by an electrode gap. In a rest position of the movable element, the same is arranged symmetrically and/or asymmetrically opposite the electrode gap. While an at least regionally symmetrical arrangement enables a deflection already at low electrical voltages and/or a symmetrical deflection, an advantageous direction and/or a mechanical pre-deflection can be implemented by means of an at least regionally asymmetrical arrangement.

According to an embodiment, along an axial path perpendicular to the layer stack direction, electrodes of the second drive structure comprise a constant or a variable lateral dimension perpendicular to the axial direction. In other words, the electrodes may provide, for example, strips having a variable strip width. A variable expansion allows for taking into account and/or compensating for mechanical stresses that may be induced by an electrode deformation.

According to an embodiment, the driving unit comprises a third drive structure mechanically firmly connected to the third MEMS layer. A first gap is arranged between the first drive structure and the second drive structure, and a second gap is arranged between the first drive structure and the third drive structure. The driving unit is configured to provide the drive force based on a first interaction between the first drive structure and the second drive structure, and based on a second interaction between the first drive structure and the third drive structure. This enables a further increase in the force deflecting the movable member and/or a precise movement of the movable member.

According to an embodiment, the driving unit is configured to generate a first drive force component based on the first interaction and a second drive force component based on the second interaction. The MEMS device is configured to generate the first drive force component or interaction and the second drive force component or interaction in-phase or with a phase shift. While an in-phase control can be used, for example, for a translational displacement of the movable element, a possibly variable but also a constant phase shift can be used for a rotation or tilting or torsion of the movable element.

According to an embodiment, the movable element is mechanically connected to the third MEMS layer via an elastic region. The movable element is configured to perform a rotational movement based on the drive force while deforming the elastic region. This enables specific implementations of the individual components.

According to an embodiment, an electrode structure is arranged on a side or MEMS layer facing the second MEMS layer and/or facing the third MEMS layer and forms at least a part of the first drive structure. This enables a high variability of the electrical variability of the electrical control.

According to an embodiment, the movable member is configured on a side facing the second MEMS layer and/or the second MEMS layer is configured on a side facing the movable member such that a surface structuring is provided to locally change a distance between the movable member and the second MEMS layer. This enables precise adjustment of electrostatic forces based on an electrode distance that is variable during movement.

According to an embodiment, electrodes of the first drive structure and/or electrodes of the second drive structure are arranged and interconnected in an interdigital manner. This enables a low level of electrical interference fields.

According to an embodiment, the MEMS device includes a multitude of movable elements arranged side by side in a common MEMS plane and coupled to each other fluidically and/or by means of a coupling element. This allows for a high level of moving fluid.

According to an embodiment, a drive structure having at least two connected electrodes arranged side by side is arranged on each of the movable elements, one electrode of which is connected to a first electrical potential and a second electrode of which is connected to a second, different electrical potential. Facing electrodes of adjacent movable elements are connected to a combination of the first electrical potential and the second electrical potential. In other words, electrodes of adjacent movable elements can be electrically controlled differently. This enables a customized control of individual elements.

According to an embodiment, the movable element is movably arranged in a MEMS cavity. By means of a movement of the movable element, at least a sub-cavity of the cavity is alternately enlarged and diminished in size, wherein the sub-cavity locally extends into the second MEMS layer. Due to the fact that the sub-cavity extends into the second MEMS layer, the corresponding MEMS space can be used efficiently.

According to an embodiment, the movable element comprises an element length along an axial extension direction perpendicular to the layer stack direction. An electrode of the first drive structure comprises a plurality of electrode segments along the element length. Adjacent electrode segments are electrically conductively connected to each other by electrical conductors. Along a direction perpendicular to the element length, the electrical conductors have a lower mechanical stiffness than the electrode segments. Through this, these regions can absorb deformation energy so that the electrode segments are deformed to a small extent, which comprises a high efficiency.

According to an embodiment, the movable element is configured to provide an interaction with a fluid. This can be done directly via direct contact with the fluid, or indirectly by the movable element moving mechanical elements provided for fluid interaction.

According to an embodiment, the driving unit comprises a fourth drive structure arranged on a side of the second MEMS layer facing away from the movable element. A further movable element is arranged adjacent to the fourth drive structure and forms a stacked arrangement with the movable element. This allows for a high level of fluid interaction with little use of chip area due to the stacked arrangement.

According to an embodiment, a method of operating a MEMS device comprises controlling two drive structures arranged along a layer stack direction along which a multitude of MEMS layers of the MEMS device are arranged, and generating a drive force at a movable element of the MEMS device perpendicular to the layer stack direction through the controlling so as to deflect the MEMS device.

According to an embodiment, the method is configured such that a symmetrical and/or linear deflection of the movable element is controlled by means of adjacent electrode elements of the drive device, said electrode elements being electrically insulated from one another by an electrode gap, by controlling the electrode elements symmetrically about a reference potential with respect to the applied potentials in the time average.

According to an embodiment, the deflection of the movable element is controlled asymmetrically in the time average along an actuation direction with respect to an opposite direction, i.e. it is controlled asymmetrically. This can be used, for example, to compensate for mechanical pre-deflections or mechanical asymmetries.

### BRIEF DESCRIPTION OF THE DRAWINGS

Particularly advantageous implementations of the present invention are explained below with reference to the accompanying drawings, in which:

FIG. 1 shows a schematic side sectional view of a MEMS device according to an embodiment;

FIG. 2a shows a schematic side sectional view of a section of a MEMS device according to an embodiment;

FIGS. 2b-d show schematic side sectional views of different deflection states of the MEMS device of FIG. 2a according to embodiments;

FIG. 3a shows a schematic side sectional view of a MEMS device according to an embodiment comprising a topography in a bottom wafer and/or cover wafer;

FIGS. 3b-d show schematic side sectional views of movable elements according to embodiments;

FIG. 4a shows a schematic side sectional view of a movable element with an electrode structure according to an embodiment;

FIG. 4b shows a schematic side sectional view of a movable element with a structured electrode structure according to an embodiment;

FIG. 5a shows a schematic top view of a part of a MEMS device for illustrating an interdigital interconnection of electrodes according to an embodiment;

FIG. 5b shows a schematic top view of a part of a MEMS device for illustrating an interdigital interconnection of structured electrodes according to an embodiment;

FIG. 6 shows a schematic side sectional view of a part of a MEMS device according to an embodiment with four movable elements according to an embodiment;

FIGS. 7a-c show schematic side sectional views of a MEMS device according to an embodiment and different implementations of electrical contacting thereof;

FIGS. 8a-c show side sectional views of a MEMS-based sound transducer according to an embodiment and in three deflection states;

FIG. 9 shows a schematic perspective view of parts of a MEMS device with movable elements clamped on both sides, according to an embodiment;

FIG. 10 shows a schematic perspective view of parts of a MEMS device with movable elements clamped on one side, according to an embodiment;

FIG. 11 shows a schematic perspective view of a part of a MEMS device according to an embodiment which may have both openings and interdigital electrodes;

FIGS. 12a-c show top views of regions of alternative implementations of an elementary cell of a MEMS device according to embodiments;

FIG. 13 shows a schematic side sectional view of parts of a MEMS device according to an embodiment, in which a movable element is formed in an H-shape;

FIG. 14 shows a schematic side sectional view of a MEMS device according to an embodiment, in which the movable element is formed in a block shape;

FIGS. 15a-c show schematic side sectional views of stacked MEMS according to embodiments;

FIGS. 16a-c show in each case a side sectional view of an alternative drive with a linear deflection behavior based on a cover drive according to embodiments;

FIGS. 17a-c show implementation of the alternative drive that is complementary with respect to FIGS. 16a-c, according to embodiments;

FIG. 18a shows a schematic top view of a MEMS device according to an embodiment which is connected to the substrate opposite to a drive structure via an elastic region;

FIG. 18b shows a schematic side sectional view of the MEMS device of FIG. 18a; and

FIG. 19 shows a schematic flow diagram of a method according to embodiments described herein.

### DETAILED DESCRIPTION OF THE INVENTION

Before embodiments of the present invention are explained in detail below with reference to the drawings, it is to be noted that identical elements, objects, and/or structures having the same function or acting in the same way are provided with the same reference signs in the different figures, so that the description of these elements shown in different embodiments is interchangeable or can be applied to each other.

Embodiments described below are described in the context of a plurality of detailed features. However, embodiments may be implemented without these detailed features. Furthermore, for the sake of clarity, embodiments are described using block diagrams as a substitute for a detailed representation. Furthermore, details and/or features of individual embodiments can be readily combined with each other as long as it is not explicitly described to the contrary.

Embodiments described herein relate to microelectromechanical devices (MEMS devices). Such MEMS devices may be multi-layered layer structures. Such MEMS may be obtained, for example, by processing semiconductor material on wafer-level, which may include combining multiple wafers and/or depositing layers on wafer planes. Some of the embodiments described herein address MEMS planes. A MEMS plane is understood to be a plane that is not necessarily two-dimensional and/or non-curved and extends substantially parallel to a processed wafer, such as parallel to a main side of the wafer or the later MEMS.

Embodiments described herein refer to layer stacks having multiple layers. However, possibly, layers described in this context are not necessarily a single layer, but may readily comprise two, three or more layers in embodiments and may be understood as a layer stack. Thus, layers from whose material a movable element is formed may be formed in multiple layers and layers between which a movable element is arranged may be configured, for example, as at least a part of a wafer and may have multiple material layers, for example for implementing physical, chemical, and/or electrical functions.

A plane direction may be understood as a direction within that plane, which may also be referred to by the term “in-plane”. Alternatively or additionally, a direction along which the layers in the layer stack alternate or are arranged may be referred to as a layer stack direction. In this respect, the plane direction, in-plane, may refer to a direction perpendicular thereto.

Some of the embodiments described herein are described in connection with a loudspeaker configuration or a loudspeaker function of a corresponding MEMS device. It is understood that these explanations, with the exception of the alternative or additional function of a sensory evaluation of the MEMS device or the movement or position of movable elements thereof, are transferable to a microphone configuration or microphone function of the MEMS device, so that such microphones constitute further embodiments of the present invention without limitation. Furthermore, other fields of application of MEMS within the scope of embodiments described herein include micropumps, ultrasonic transducers, or other MEMS-based applications related to a movement of fluid. For example, embodiments may relate to a movement of actuators that may interact with a fluid, among other things.

Embodiments relate to an application of electrostatic forces for a displacement of a movable element. However, the described embodiments may readily be implemented using other drive principles, such as electromagnetic force generation or sensing. The deflectable elements may be, for example, electrostatic, piezoelectric and/or thermomechanical electrodes that provide a deformation based on an applied potential.

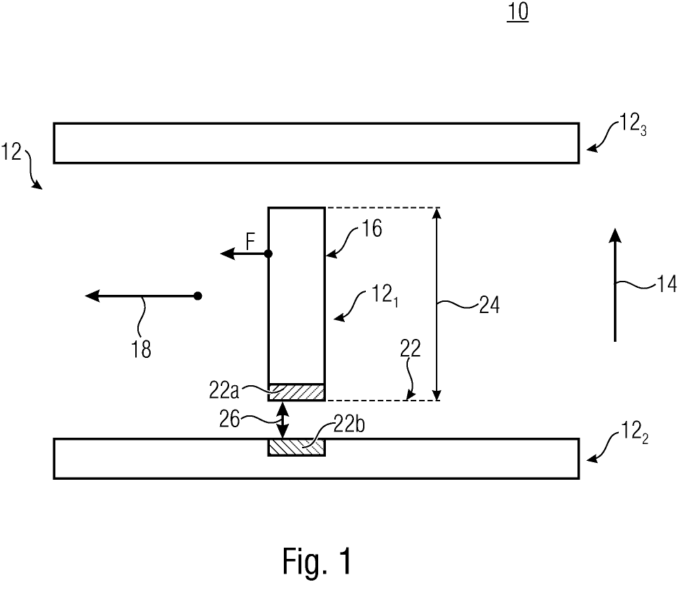

FIG. 1 shows a schematic side sectional view of a MEMS device 10 according to an embodiment. The MEMS device includes a layer stack 12 that may include a plurality of layers 12₁, 12₂, with optional additional layers 12₃ and possibly additional layers being part of the layer stack 12. Some of the layer stacks (or sequences) may be mechanically connected to each other, but distances may also be provided in regions between adjacent layers. Also, some of the layers of the layer stack 12 may be locally spaced apart, such as is shown for the MEMS layer 12₁. Here, the layer 12₁ arranged with the layers 12₂ and 12₃ along a layer stack direction 14 may be locally removed to expose a movable element 16 so that the movable element 16 is movable at least relative to the layer 12₂. Here, at least one component of the movement is perpendicular to the layer stack direction 14 along a plane direction 18, i.e. in-plane. As will be explained in the context of embodiments, this may include a translational movement along the plane direction 18 and/or a rotational component, such as for a torsional movement.

The movable element 16 is arranged between the layers 12₂ and 12₃, wherein a driving unit (or driving means) 22 is provided to generate on the movable element 16 a drive force F along the plane direction 18, the drive force F being adapted to deflect the movable element 16. The force F may be generated in some implementations and nearly perpendicular to the layer stack direction, although other directions are possible, for example for torsional movements.

The driving unit comprises a drive structure 22a that is mechanically firmly connected to the movable element. Further, the driving unit 22 comprises a drive structure 22b that is mechanically firmly connected to the MEMS layer 12₂. In the context of embodiments described herein, mechanically firmly connected is understood to mean mechanically firmly arranging another element at another element, for example by means of a fixation, such as by an adhesive, by bonding, coating, soldering, or the like. Alternatively or additionally, for example, a conductive layer may be arranged on another layer to mechanically firmly arrange at least a part of the drive structure on a layer. Alternatively or additionally, mechanically firmly connected is also understood such that, for example, an electrically conductive structure is an integral part of another structure. For example, in an advantageous implementation, doping a semiconductor material may render the same electrically conductive, for example, to provide the function of an electrode. This electrode is also understood to be mechanically firmly connected to the respective element, even if it is the same element from another point of view.

According to an embodiment, for example, the movable element 16 is configured to be electrically conductive, such as by comprising electrically conductive materials, such as a metal material and/or a doped semiconductor material. Alternatively or additionally, the drive structure 22a may be deposited, for example, in the form of an electrode structure on a base body of the movable element 16. In an analogous manner, for example, the drive structure 22b may comprise electrically conductive materials, for example in terms of an at least regional doping of a semiconductor material of the layer 12₂ and/or by arranging an electrode structure.

Configuring the MEMS device 10 such that a movement of the movable element 16 occurs in-plane and the drive structure is arranged along the layer stack direction 14 enables obtaining a comparatively large dimension 24 of the movable element 16 along the layer stack direction 14, which is, for example, at least 75 µm, at least 100 µm, at least 500 µm, or more. A comparatively large region can be exposed along the plane direction 18, said region being in accordance with aspect ratios of known exposure methods, for example the Bosch method. Through this, the drive structure 22 may have a gap 26 between the drive elements 22a and 22b that is independent of such an exposure method. That is, the drive structures 22a and 22b may be spaced apart and opposed to each other by the gap 26, for example in a rest position of the movable member 16. A dimension of the gap 26 along the layer stack direction 14 may be adjusted by a bonding process.

For example, a dimension of the gap 26 may be at least partially determined by joining the layer stacks along the layer stack direction 14, which may allow for a comparatively small dimension of the gap 26 compared to, for example, an etching process, such as 10 µm or less, 5 µm or less, or 1 µm or less. Compared to the gap 26, a corresponding aspect ratio of the dimension 24 may be correspondingly high, which is advantageous for the MEMS device 10 since interaction with a large volume of fluid is possible.

In this regard, the movable element 16 may be formed to be single-layered or multi-layered. For example, the movable element 16 may have a plurality of at least two, at least three, at least four, at least five, or more layers joined together, for example, by a bonding process. For example, different silicon layers can be connected as part of a bonding process of silicon wafers in order to obtain overall a high layer thickness or a large dimension 24, which, for example, may establish a decreased dependence or even independence on the aspect ratio of the etching process, such as the Bosch method.

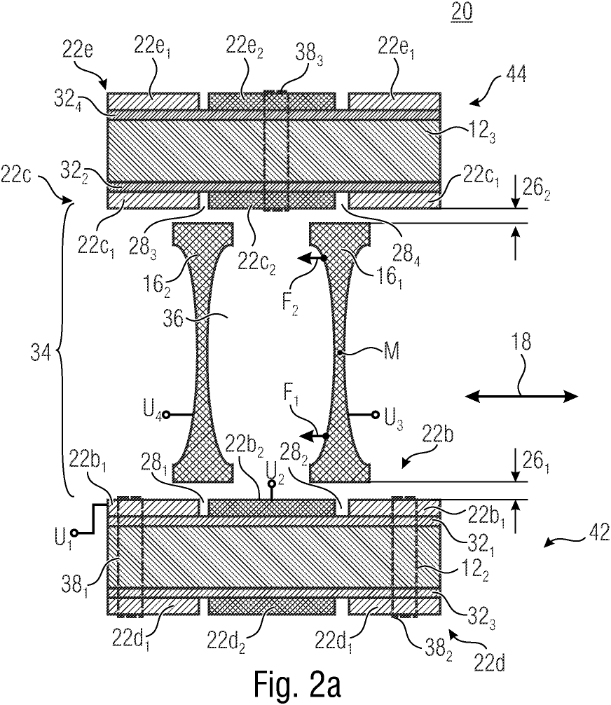

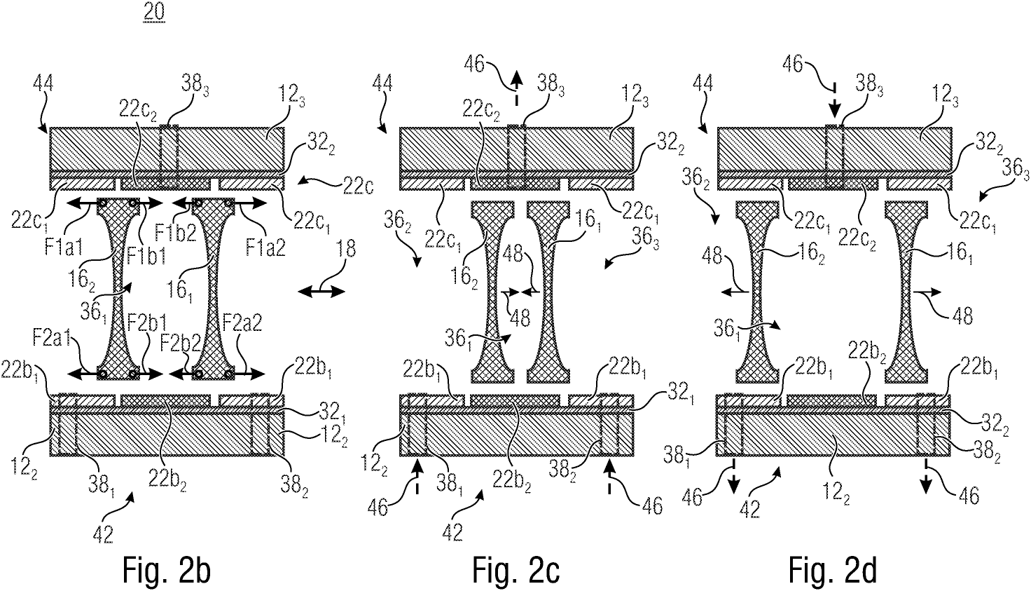

FIG. 2a shows a schematic side sectional view of a section of a MEMS device 20 according to an embodiment. The drive structure 22b of the driving unit is, for example, a structured electrode structure and comprises at least one electrode element 22b₁ and one electrode element 22b₂ that are electrically insulated from each other so that a first electrical potential can be applied to the electrode element 22b₁ and a second electrical potential different therefrom can be applied to the electrode element 22b₂. This includes, for example, alternately applying potentials of the same or different amplitude to the electrode elements 22b₁ and 22b₂ but can also mean simultaneously applying the same or different potentials to the electrode elements 22b₁ and 22b₂, depending on which control of the MEMS device 20 is desired or entailed.

For electrical insulation, gaps 28₁ to 28₄ may be provided between the electrode segments, which may optionally be filled with electrically insulating material or dielectric material.

The MEMS device 20 may include a plurality or multitude of movable elements 16₁ and 16₂, and optionally further movable elements, arranged side-by-side along the plane direction 18. The drive structure 22a described in connection with FIG. 1 may be part of one, a plurality, or all of the movable elements 16₁ and 16₂.

The movable element 16₁ may be arranged symmetrically opposite the electrode gap 28₂, for example to obtain symmetrical actuation. Alternatively, it is also possible to arrange the movable element asymmetrically opposite the electrode gap 28₂, for example to obtain asymmetrical actuation. Similarly, the movable element 16₂ may be arranged symmetrically or asymmetrically opposite the electrode gap 28₁.

Exemplarily, different potentials U₃ and U₄ can be applied to the movable elements 16₁ and 16₂, wherein, according to embodiments, the movable elements 16₁ and 16₂ or their drive structures are electrically or galvanically connected to each other so that the potentials U₃ and U₄ are the same or identical. Based on the potentials U₁, U₂, U₃ and U₄, electrostatic forces that can lead to a deflection of one or more movable elements 16₁ and/or 16₂ along the direction of movement of the plane direction 18 can be generated. Through this, in interaction of the electrical potential of the moving structure and the potential U₁ and/or U₂, the drive force can be generated.

The drive structure 22b may comprise an electrode structure advantageously formed in a structured manner, such as in the form of interdigital electrodes. This means that further electrode elements connectable to the potential U₂ may also be part of the drive structure 22b. According to further embodiments, however, individual electrode segments may also be electrically insulated from each other so that, for example, the electrode elements collectively provided with reference numeral 22b₁ form electrode elements to which potentials may be applied individually.

As it is shown in FIG. 2a, further drive structures 22c, 22d and/or 22e may be arranged at sides of the layers 12₂ and 12₃ facing the and facing away from the movable elements 16₁ and 16₂ In this case, the additional drive structures 22c, 22d and 22e are optional. In particular, the drive structures 22d and 22e may be provided in a stacked arrangement of the MEMS device for arranging additional movable elements 16. Similarly, as the movable elements 16₁ and 16₂ are shown adjacent to the drive structures 22b and 22c, additional movable elements may be arranged adjacent to the drive structures 22d and/or 22e.

For example, the drive structure 22c at the MEMS layer 12₃ or the wafer 44 may be used to provide an additional drive force component between the movable element 16₁ and/or 16₂ and the drive structure 22c in addition to the drive force component using the drive structure 22b. This means that, with respect to the description of the MEMS device 10, at a movable element 16, a first interaction between the movable element 16₁ and the drive structure of the wafer 42 and a second interaction between the movable element 16 and the drive structure of the wafer 44 may be provided. For example, such control may take place through a control unit (or control means) configured to apply corresponding voltages or potentials or control signals to the electrodes or conductive structures. The driving unit may be configured to generate a first drive force component F₁ based on the first interaction, and a second drive force component F₂ based on the second interaction. The MEMS device may be configured to generate the first force component and the second force component in the same direction or in-phase, which may allow for a back-and-forth movement of the movable element 16₁ parallel to the plane direction 18, for example. A phase shift between the force components F₁ and F₂ may result in a tilt or rotation about a suspension center M, for example a torsion of the movable element 16₁. Also in case of an inversely phased control, a configuration of the force components F₁ and F₂ may enable a back-and-forth rotation of the movable element 16₁, for example, about the center point or center axis M. This means that it is possible for the upper and lower drive structures to provide force components that are displaced relative to each other based on individual control.

The driving unit may comprise a further drive structure that may be arranged on a side of the MEMS layer 12₂ and/or 12₃ facing away from the movable element 16₁ and/or 16₂, where a further movable element may be arranged adjacent to said drive structure to form a stacked arrangement with the movable element 16₁ and 16₂.

For example, the electrode structures may be connected to the layers 12₂ and/or 12₃ via connection layers 32₁ to 32₄, which may be particularly advantageous if the layers 12₂ and/or 12₃ are formed from semiconductor material. For example, the layers 32₁ to 32₄ may be formed in an electrically insulating manner and comprise, for example, silicon oxide and/or silicon nitride. Other material choices are also possible without limitation.

The movable elements 16₁ and 16₂ may optionally be arranged symmetrically across the gaps 28₁ to 28₄, which may enable symmetrical control of the movable elements 16₁ and 16₂, for example for linear movement. Notwithstanding this, positions deviating therefrom may also be provided, for example in a rest position, in order to implement an asymmetrical control, for example.

The movable elements 16₁ and 16₂ may be moved towards and away from each other during a control cycle, but alternatively may be moved in-phase, such that, for example, a distance between the movable elements 16₁ and 16₂ is equal or only changed insignificantly. In the other case in which the movable elements 16₁ and 16₂ are alternately moved towards and away from each other, for example, the volume of a sub-cavity 36 between the movable elements 16₁ and 16₂ may be alternately reduced and increased. For a fluidic exchange with an environment, openings 38₁ to 38₃ may be provided in any number and/or position in a first wafer 42 and/or second wafer 44 that may provide, for example, a bottom wafer and/or cover wafer between which the movable element 16₁ and/or 16₂ is arranged so that fluid can flow into or out of the sub-cavity 36.

FIG. 2b shows a schematic side sectional view of a part of the embodiment of FIG. 2a, in which, for example, the optional drive structures 22d and 22e are not shown.

In a comparable manner, FIGS. 2c and 2d show the corresponding section of the MEMS device 20, wherein in FIG. 2c, starting from an exemplary resting state of FIG. 2b, a movement 48 of the movable elements 16₁ and 16₂ towards each other has taken place so that the volume of the sub-cavity 36₁ between the movable elements 16₁ and 16₂ is reduced, while the volumes of sub-cavities 36₂ and 36₃ adjacent to the movable elements 16₁ and 16₂ are correspondingly increased on sides facing away from the sub-cavity 36₁, so that correspondingly arranged openings 38₁ and 38₂ can let fluid 46₃ flow into the sub-cavities 36₂ and 36₃ while the openings 38 can let fluid 46 flow out of the sub-cavity 36₁.

FIG. 2d shows a complementary state in which the movement 48 is performed such that the movable elements 16₁ and 16₂ move away from each other, which may cause the volume of the sub-cavity 36₁ to increase again while the volumes of the sub-cavities 36₂ and 36₃ are reduced so that the fluid 46 can flow in the opposite direction, for example through the opening 38₃ into the sub-cavity 36₁ and through the openings 38₁ and 38₂ out of the sub-cavities 36₂ and 36₃, respectively.

To this end, FIG. 2b shows exemplary force vectors F1a1, F1b1, F1b2, F1a2, F2a1, F2b1, F2b2, and F2a2 indicating that a movable element 16₁ exemplarily formed to be electrically conductive and/or a movable element 16₂ exemplarily formed to be electrically conductive can generate, based on potentials of the electrode elements of the drive structures 22b and 22c, forces that can trigger the movement 48 of FIG. 2c or the movement 48 of FIG. 2d.

As can be seen from FIGS. 2a to 2d, a plurality of movable members 16 may be arranged along the plane direction 18 to alternately diminish in size and enlarge adjacent sub-cavities during control so as to move a large level of fluid, which is particularly advantageous for pump applications or loudspeaker applications.

In other words, the electrically conductive layers 22b and 22c may be divided in a first direction into at least two discrete sub-regions 22b₁ and 22b₂ and 22_{C1} and 22c₂. These sub-regions are electrically insulated from each other and separated by a distance 28 or an insulating medium therein, for example silicon oxide, and may constitute electrodes. The arrangement and interconnection of the electrodes is exemplarily configured to be interdigital. The distance of the sub-regions is, for example, 1 µm, but may also be 10 nm or even up to 10 µm. A first group of sub-regions 22_{C1} and 22c₂ is, by way of example, mechanically connected to the cover wafer via an insulating connection layer 32₂. Another second group of sub-regions 22b₁ and 22b₂ is mechanically connected to the bottom wafer via an insulating connection layer 32₁. In one group of sub-regions, such as 22b₁ and/or 22c₁, a first sub-region is connected to a first signal voltage, and a second sub-region 22b₂ and/or 22c₂ is connected to a second signal voltage. For example, the signal voltages may have the same magnitude, but may also be shifted by, for example, phases of 180°. The phase shift may also have other values. Electrically identical sub-regions of the respective groups may be arranged opposite each other at the cover wafer and bottom wafer.

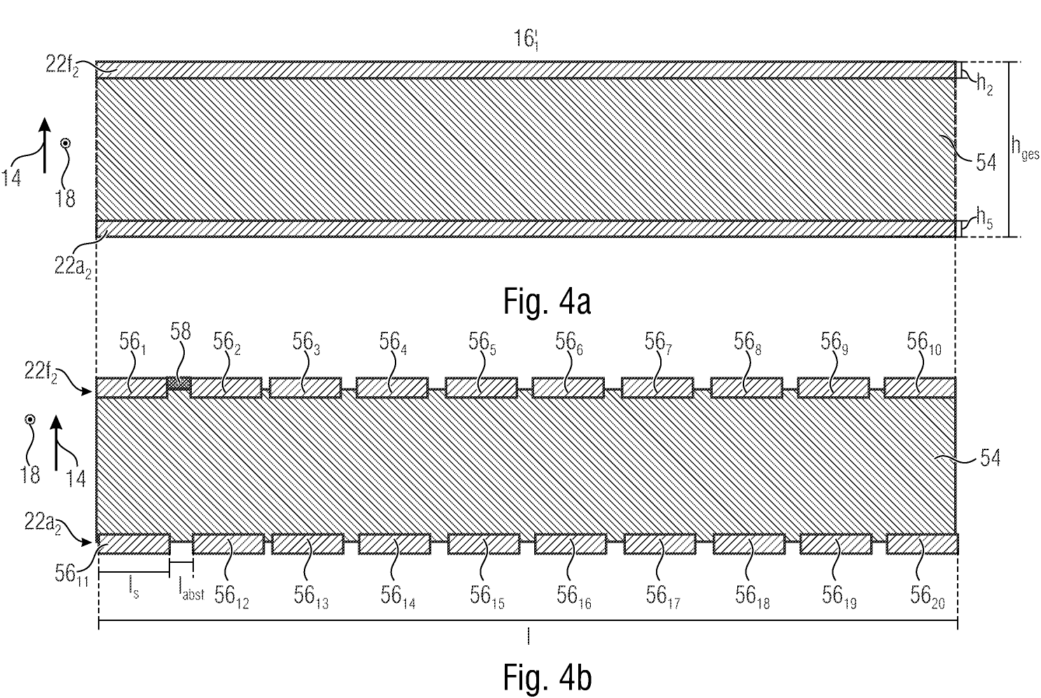

The following describes the arrangement and geometrical configuration of the resistive elements 16₁ to 16ₙ, wherein n may be an integer multiple of a, i.e. an integer. The resistive elements, i.e. the movable elements, may be, for example, beam-shaped elements having their longitudinal extension direction in a second direction arranged perpendicularly to the above-mentioned first direction, such as along a surface centroid fiber. Such a dimension is indicated in FIG. 4a and FIG. 4b, for example, by the parameter I. Advantageous lengths are, for example, between 10 µm and 10 mm, particularly advantageous lengths are between 1 mm and 6 mm, and particularly advantageous lengths I are approximately 3 mm. The extension of the resistive elements in the first direction, i.e. parallel to the direction of movement, is much smaller than the extension in the second direction. It should be noted here that a particularly advantageous embodiment of a resistive element comprises a variable width, e.g. along the first direction. The width of the resistive element is smallest in the region of its surface centroid fiber and may be located in the region of the neutral axis of the resistive element, see in this regard the point M. Towards its upper and lower edges, the width at the edge of the movable element may increase again. For example, the width in the region of the surface centroid fiber is a value between 3 µm and 4 µm. The width shown in the region of the upper and lower edges is, for example, a value between 7 µm and 8 µm. The width of the beam can also be configured the other way round, i.e. so as to be thinner in the middle and thicker at the edge or thicker in the middle and thinner at the edge.

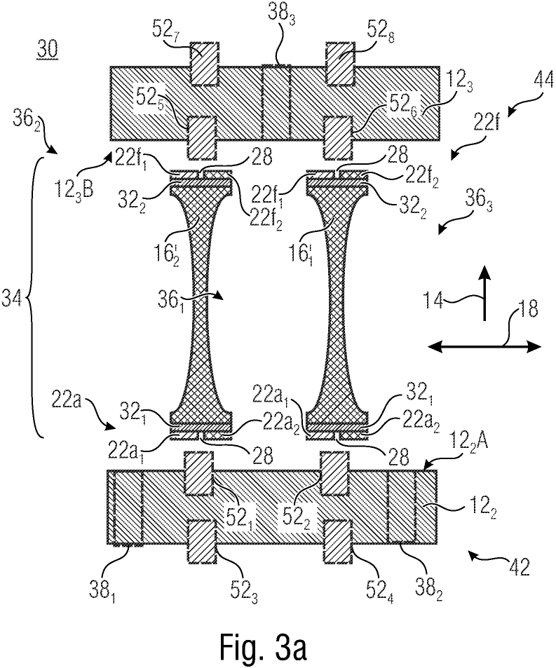

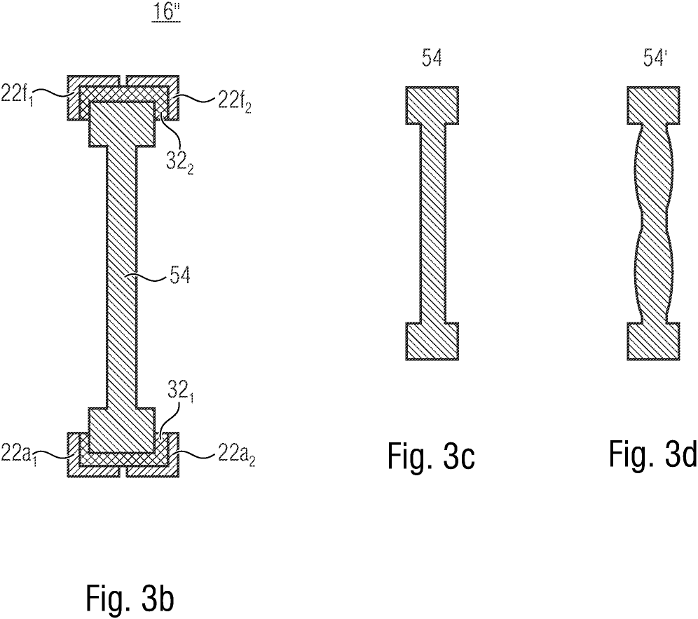

The extension, which may be referred to as the height, for example, and which extends in a third direction arranged perpendicularly to the plane spanned between the first and second directions, for example along the distance 34, is for example between 400 µm and 5000 µm, advantageously between 650 µm and 1500 µm and particularly advantageously approximately 1000 µm. The shape of the resistive elements in its width may be different, as is also illustrated with reference to FIGS. 3a to 3d.

The resistive elements are arranged to equally overlap two adjacent sub-regions (22c₁ and 22c₂, and 22b₁ and 22b₂) in the cover and bottom wafer regions. The insulating region between two sub-regions 38 is also included in this overlap. The insulating region 28 between two sub-regions may be made of oxide (e.g. SiO₂, Si₃N₄ or Al₂O₃) or air and may have a width of between 0.1 µm and 10 µm.

The resistive elements 16₁, 16₂ have a distance 26₁, 26₂ from the electrodes of the electrically conductive layers. The same is, for example, between 0.01 µm and 10 µm, advantageously between 0.05 µm and 1 µm and particularly advantageously a distance of 0.1 µm. This distance forms the two-part capacitive actuator between the beam, and the cover and bottom wafers. Thus, the actuator that is to move the resistive structures/beams has no direct mechanical contact with the resistive structure. This distinguishes this solution from the other solutions, where the actuator and the resistive structures must be mechanically connected to obtain an acoustic effect from the resistive structures.

The balanced actuators (actuator with linear deflection behavior) according to FIGS. 2a-d show different time moments upon actuation of the resistive elements:

The forces acting on a resistive element are shown below:

The force pulling to the left (first movement direction):

$$\begin{matrix}{\text{F}}_{\text{a1}} = {\text{F}}_{1 \text{a} 1} + {\text{F}}_{\text{2a1}} = \\ \sim {\left({\text{U}}_{\text{DC}} + {\text{U}}_{\text{ACa}}\right)}^{2} / \text{d}\end{matrix}$$

U_{ACa} = the signal voltage/AC voltage applied to electrodes 2a and 5a.

The force pulling to the right second movement direction):

$${\text{F}}_{\text{b1}} = {\text{F}}_{1 \text{b} 1} + {\text{F}}_{\text{2b1}} = \sim {\left({\text{U}}_{\text{DC}} + {\text{U}}_{\text{ACb}}\right)}^{2} / \text{d} ;$$

U_{ACb} = the signal voltage/AC voltage applied to electrodes 22_{C1}/22_{C2} and 22b₁/22b₂.
U_{DC} is the DC voltage applied between the cover/bottom wafer and the device wafer.
d = distance between cover/bottom wafer and device wafer, 26₁, 26₂.

The resulting force on a resistive element is:

$${\text{F}}_{1} = {\text{F}}_{\text{a1}} {\text{- F}}_{\text{b1}} = \sim \left(2 {\text{*U}}_{\text{DC}} {\text{*U}}_{\text{ACa}} {\text{- 2}}_{\text{UDC}} {\text{*}}_{\text{UACb}} + {\text{U}}_{{\text{ACa}}^{2}} {\text{- U}}_{{\text{ACb}}^{2}}\right) / \text{d}$$

If the signal voltage/AC voltage ᵢₛ U_{ACa}= - U_{ACb} = U_{AC}, then the following applies

$${\text{F}}_{1} = \sim 4 {\text{*U}}_{\text{DC}} \text{*} {\text{U}}_{\text{AC}} / \text{d} .$$

The resulting force is linearly dependent on the signal voltage U_{AC}. The linearity between signal voltage and force is of very high importance for the sound quality of a loudspeaker (distortion factor).
a) The following applies for an equilibrium of forces: 22_{C1} and 22c₂ or 22b₁ and 22b₂ have the same voltage U_{ACa} = U_{ACb} the forces are all equal Fₐ₁ = F_{b1} and Fₐ₂ = F_{b2}: The resistive elements are equally located under 22_{C1}/22_{C2} and 22b₁ /22b₂, respectively;
b) The following applies for the movement of the resistive elements under 22_{C2}/22b₂: Voltage U_{ACa} < U_{ACb}. The forces have the following relationship: Fₐ₁ < Fb1 and Fₐ₂ < Fb2, respectively;
c) The following applies for the movement of the resistive elements under 22_{C1}/22b₁: U_{ACa} > U_{ACb}. The forces have the following relationship: Fₐ₁ > F_{b1} and Fₐ₂ > F_{b2}, respectively;

FIG. 3a shows a schematic side sectional view of a MEMS device 30 according to an embodiment that is modified with respect to several optional modifications with respect to the MEMS device 20. While the principle effect of movable elements 16₁ and 16₂ being moved toward or away from each other may be the same, such as to increase or decrease volumes of sub-cavities 36₁, 36₂ and 36₃ to move fluid through openings 38₁, 38₂ and 38₃, a movable element 16′₁ or 16′₂ of the MEMS device 30 comprises a modified configuration.

In contrast to the MEMS device 20, where the movable elements 16 are exemplarily formed to be integrally electrically conductive, the movable elements 16′₁ and 16′₂ may be formed of a semi-conductive or non-conductive material such that the drive structure 22a and/or 22f is mechanically firmly connected to the movable element by means of layers 32₁ and/or 32₂, or a base body thereof, and includes electrode elements 22a₁, 22a₂, 22f₁ and 22f₁. That is, on contrast to the MEMS device 20, where electrode structures are arranged on the substrate layers 12₂ and 12₃, electrode structures may alternatively or additionally be provided on the movable elements 16′₁ and 16′₂. In this regard, the drive structures 22a and 22f may be controlled or interconnected in the same or identical manner and may, for example, be brought to an identical potential, such as for the electrode elements 22a₁ and 22f₁ and 22a₂ and 22f₂, although an individual interconnection may alternatively be provided. That is, an electrode structure may be arranged on a side of the MEMS layer 12₁, or of the movable element, facing the MEMS layer 12₂ and/or the MEMS layer 12₃, and form at least part of the drive structure.

In the MEMS device 30, on the other hand, the layers 12₂ and/or 12₃ may optionally be formed to be electrically conductive so that a separate arrangement of electrode structures may be omitted. Alternatively, the layers 12₂ and 12₃ may also be provided with electrode structures as described in connection with the MEMS device 20.

Independent of this but also in combination, the layers 12₂ and 12₃ may have surface topographies 52₁ to 52₈ that may be provided, for example, for symmetrical control in the region of opposing electrode gaps 28 and may be implemented in the form of elevations or depressions opposite main sides 12₂A or 12₃B, i.e. the distance between the movable element and the layer 12₂ or 12₃ in the region of the topographies 52 may be locally increased by implementing the topography as a depression in the material or locally decreased by implementing the topography as an elevation. In some embodiments, this surface topography may be desired or used. For example, if the electrodes are arranged on the movable element, it is advantageous to structure the bottom wafer and/or cover wafer (or top wafer) to be identical or similar to what is shown so as to obtain a movement. Through the topographies 52, an adjustment of electrostatic forces can be obtained. In other words, surface topographies 52 may be elevations or holes. Such structuring may be symmetrically arranged on both sides of the wafers 42 and/or 44. That is, the movable element 16′₁ and/or 16′₂ may have a surface structuring or surface topography on a side facing the second MEMS layer 12₂ and/or the second MEMS layer 12₂ on a side facing the movable element 16′₁ to 16′₂ so as to locally change a distance between the movable element 16′₁ and 16′₂, respectively, and the second layer 12₂.

While the surface topographies 52₁, 52₂, 52₅, and 52₆ may be used to adjust the electrostatic forces between the drive structures for the illustrated control, the surface topographies 52₃, 52₄, 52₇, and 52₈ may be used as dummy structuring, for example, to avoid bending of wafers 42 and/ or 44 as much as possible. Referring to the structured electrically conductive layers or electrodes 22c/22e and 22b/22d in FIG. 2a, it should be noted here that, using a structuring of the electrodes 22e with the same effect in sub-regions with respect to the sub-regions of the electrically conductive layer 22c and/or using a structuring of the electrodes 22d with the same effect in sub-regions with respect to the sub-regions of the electrically conductive layer 22b, a similar or identical effect can be obtained in the sense of avoiding bending, irrespective of whether further movable elements not shown in FIG. 2a are arranged adjacent to the electrically conductive layers 22d and/or 22d.

Optionally, however, in an embodiment with a stacked arrangement of movable elements, e.g. adjacent to the drive structure 22d and/or 22e in FIG. 2a, corresponding adjustment possibilities perpendicular to the direction of movement 18 or along the layer stack direction 14 can also be obtained for the additional movable elements not shown.

FIG. 3b shows a schematic side sectional view of a movable element 16″ according to an embodiment, for example, which can be used to be employed in the MEMS device 16 as a movable element 16′₁ or 16′₂. A base body 54 of the movable element 16″ may, for example, be formed of semiconductor material, such as silicon, and may, for example, have an approximately rectangular geometry, wherein thickenings may also be provided at ends of the base body 54.

Unlike a plane arrangement of the electrode structures according to FIG. 3a, the electrodes 22a₁, 22a₂, 22f₁ and/or 22f₂ may also be partially arranged on side surfaces of the movable element 16″ or the base body 54, which makes it possible, for example, to also generate electric fields along these sides, which may be advantageous in the case of a dynamic movement of the movable element 16″.

The shape of the base body 54 is independent of the implementation of the electrodes on the side surfaces. Such an implementation is readily also possible at the movable elements 16₁ and 16₂.

In other words, FIGS. 3a and 3b show a so-called balance actuator. FIG. 3a and FIG. 3b show an alternative embodiment of an elementary cell with linear deflection behavior. The difference to the embodiment in FIGS. 2a-d is the location of the electrically conductive layers at the resistive elements. Due to this alternative location, the resistive element is an active resistive element. Here, the resistive element is characterized in that the electrically conductive layers are each connected to the resistive element via an electrically insulating layer. The shape of the resistive elements with the conductive layers can be different in their width.

Furthermore, an alternative deflectable and active resistive element is also shown (FIG. 3b). Here, the electrically conductive layers are arranged partially around the periphery of the resistive element. In other words, electrically conductive layers are arranged not only between the resistive element and the cover wafer and between the resistive element and the bottom wafer, but also on the sides of the resistive elements enclosing the cavities.

FIG. 3c shows a schematic side sectional view of the base body 54 of FIG. 3b. FIG. 3d shows a schematic side sectional view of a base body 54′ modified with respect to FIG. 3c, which comprises a configuration that is convexly curved multiple times, in contrast to the single concave configuration of FIG. 2a.

In a cross-section, the movable element may be polygonal, such as rectangular, curved once or curved multiple times, wherein a curvature may be convex or concave, wherein a multi-curvature also allows mixed forms thereof. Alternatively or additionally, in the cross-section along the layer stack direction 14, the movable element may have a variable dimension perpendicular to the layer stack direction, for example along the plane direction 18.

FIG. 4a shows a schematic side sectional view of the movable element 16′₁ of the MEMS device 30 according to a first embodiment of the electrode structures. For example, the electrode segments 22f₂ and 22a₂ may be arranged opposite each other on the base body 54 irrespective of the cross-section thereof and may, for example, provide a planar contact along a length I. In this regard, the electrode segment 22a₂ may have a height h₅ and the electrode segment 22f₂ may have a height h₂ along the layer stack direction 14, which may result in an overall height h_{ges} of the movable element 16′₁.

FIG. 4b shows a schematic side sectional view of an alternative embodiment, in which both the electrode element 22f₂ and the electrode element 22a₂ are structured into segments 56₁ to 56₁₀ and 56₁₁ to 56₂₀, respectively, wherein the number of 10 segments 56 is merely exemplary and may be any number of at least two, at least three, at least five, at least eight, at least ten, or more.

As exemplarily illustrated for the connection 58, the segments 56 of an electrode 56f₂ and 22a₂, respectively, are electrically or galvanically coupled to each other so that they have the same potential when an electrical potential is applied within the group 56₁ to 56₁₀ and 56₁₁ to 56₂₀.

Here, a segment can have a dimension Iₛ that, for example, comprises a value in a range between 0.5 µm and 2 µm, although other values can also be implemented on the basis of individual configurations. A distance l_{abst} that is constant or also variable over the length I can be provided between two adjacent segments 56, wherein said distance spaces apart two segments 56 from one another, but is bridged by means of an electrically conductive connection 58.

That is, the movable element may be configured across an element length I along an axial extension direction perpendicular to the layer stack direction such that the electrode 22a₂ and/or 22f₂ comprises a plurality of electrode segments 56. Adjacent electrode segments 56 may be electrically connected to each other by electrical conductors 58, wherein the electrical conductors have a lower mechanical stiffness along the direction perpendicular to the element length, for example along the plane direction 18, than the electrode segments. Hereby, it can be achieved that a movement or deformation of the movable elements is hindered by a mechanical stiffness of the electrode material to a small extent.

In other words, the electrically conductive layers may be segmented in the first direction as shown in the side view in FIG. 4b. In this case, the segments are spaced apart from each other. Advantageously, the stiffness of the deflectable elements can thus already be addressed in the design. In this case, the resulting gaps are advantageously not filled. FIG. 4b thus shows a view of an embodiment with segmented electrode layers.

The extension of the resistive elements in the third direction is denoted, inter alia, by h in FIG. 4a and the extension of the electrically conductive layer 22a or 22f is denoted by h₂ or h₅. The ratio of h to h₂ or h to h₅ is 20%, advantageously 5% or particularly advantageously 1%, i.e. h₂ and h₅ are thinner than the body 54.

The extension of the resistive elements in the first direction is illustrated, inter alia, in FIG. 4b. Here, an alternative arrangement of the conductive layers 22a and 22f is illustrated, which, as already mentioned above, reduce the stiffness of the deflectable element. The length of the resistive element in the first direction is denoted by I. The length of a segment is denoted by Iₛ. The distance between the segments is denoted by I_{abst}.

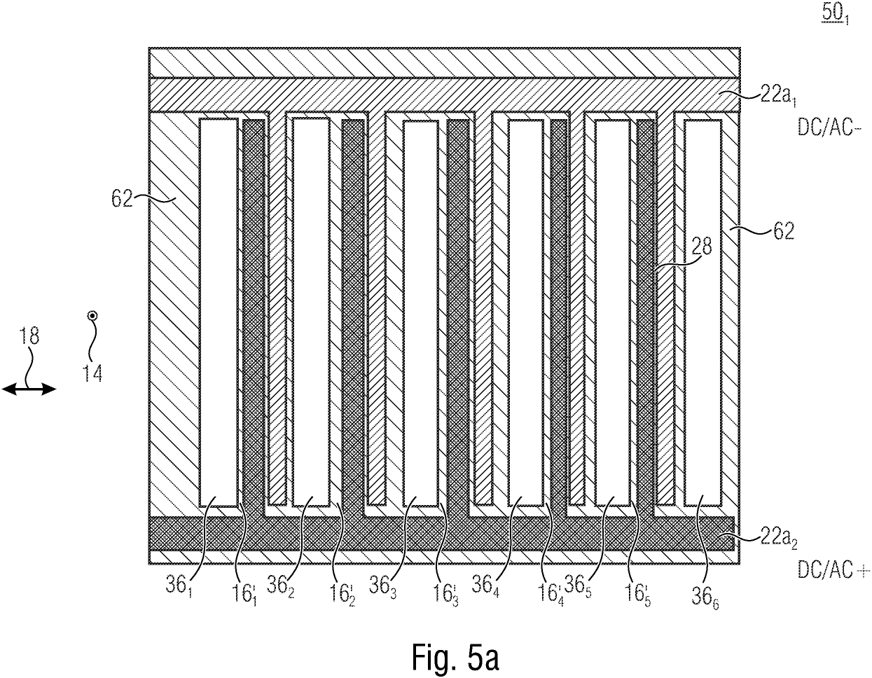

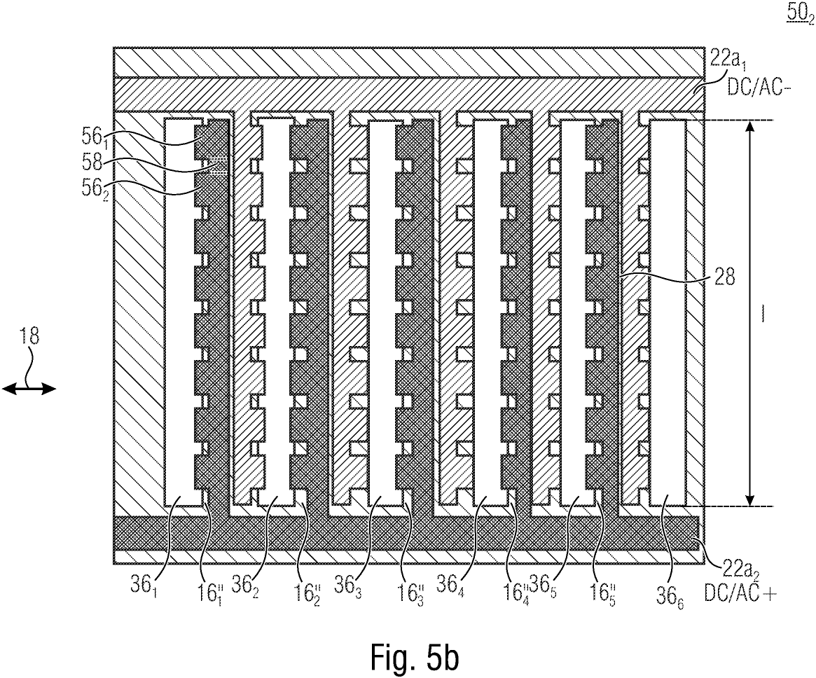

FIG. 5a shows a schematic top view of a part of a MEMS device 50₁ according to an embodiment, in particular the embodiment of the movable elements 16′₁ to 16′₅, which may be exemplarily formed in correspondence with the movable elements 16′₁ and 16′₂ of the MEMS device 30. Sub-cavities 36₁ to 36₆ are arranged between adjacent movable elements or between a movable element and surrounding substrate 62 for the case of movable elements 16′₁ and 16′₅. The movable elements 16′₁ to 16′₅ may be regarded as beams that are fixedly clamped on both sides, wherein the interdigital interconnection of the electrode elements 22a₁ and 22a₂ is shown by way of example. It can be seen that the respective electrode elements of adjacent movable elements 16′₁ to 16′₅ may have the same potentials due to the continuous interconnection, but that separating such a configuration may also result in an individual interconnection.

A direct current (DC) voltage may be applied to the electrode elements 22a₁ and 22a₂ so that, for example, the DC voltage is alternately applied to the electrodes 22a₁ and 22a₂. Alternatively, an AC voltage may be applied, as indicated by ACand AC+. Such a configuration may also take place simultaneously, which may, for example, result in attractive forces between adjacent movable elements to move them towards each other.

In other words, FIG. 5a shows a schematic illustration of a contacting of the electrodes when they are connected to the beam, the movable elements. Similarly, such a configuration can also be implemented for electrodes facing the cover wafer and/or the bottom wafer.

As can be seen from FIG. 5a, the movable elements 16′₁ to 16′₅ may be configured directly to interact with the fluid, for example by the main bodies moving the fluid or being moved by the fluid. Alternatively, additional elements, such as plate elements or the like, that are moved by the movable elements and in turn interact with the fluid could be arranged on the movable elements.

FIG. 5b shows a schematic top view of a MEMS device 50₂ according to an embodiment in a view comparable to FIG. 5a. However, unlike the MEMS device 50₁, the movable elements are formed as movable elements 16″ as shown, for example, in FIG. 3b. That is, in addition to a top or bottom surface, the electrodes 22a₁ and 22a₂ also extend on side walls of the movable elements, although it should be noted here that terms such as up, down, left, right, front, rear, and the like are not limiting, but are merely illustrative, since it is clear that the terms are mutually interchangeable due to a change of orientation of the bodies in space.

However, it can be seen that, upon a movement or deformation of the movable elements 16″₁ to 16″₅ along the direction of movement 18, an advantage can be obtained if the electrodes are structured as explained in connection with FIG. 4b or FIG. 5b. The electrical connection 58 between two adjacent segments 56₁ and 56₂ can be made, for example, by thinning or removing the corresponding electrode locally, but this can lead to low mechanical resistances of the electrode elements when the curvature of the movable element 16″₁ is carried out.

In this regard, the sub-cavities 36₁ to 36₆ may be parts of an overall cavity, and the sub-cavities 36₁ to 36₅ may be alternately enlarged and reduced in size due to the movement of the movable elements 16″₁ to 16″₆.

The movable elements of the MEMS devices 50₁ and 50₂ may be fluidically coupled to each other, so that, upon actuation of only one of the movable elements, an adjacent movable element may also be moved in the unactuated state. That is, the movement of the fluid potentially couples over to an adjacent movable element regardless of whether it is actuated or unactuated. Optionally, adjacent movable elements may also be coupled to each other by means of a coupling element, which is not shown, for example in a central region, such as I/2 or the like. Such a coupling element makes it possible to perform a uniform movement of the coupled movable elements.

As further shown in MEMS devices 50₁ and 50₂, different potentials may be applied to electrodes 22a₁ and 22a₂. In this regard, the interdigital structure may be formed such that electrodes of adjacent movable elements facing each other are connected to a combination of the potentials AC- and AC+, that is, the electrodes facing each other both have different potentials or, in other words, different potentials of the different electrodes 22a₁ and 22a₂ face each other. This is also true for the DC connection, which, for example, is done so as to alternate between the electrodes 22a₁ and 22a₂ so that a connected electrode faces an unconnected electrode.

In other words, FIGS. 5a and 5b show top views of the embodiments of FIGS. 4a and 4b, respectively, with FIG. 5b also showing contacting of the electrodes when connected to the beam. FIGS. 5a and 5b are top views of the layers of FIG. 4a/FIG. 4b of a MEMS-based transducer with linear deflection behavior in a simplified embodiment with a limited number of actively deflectable elements. The illustration shows a possible electrical connection of the actively deflectable resistive elements as shown in FIGS. 4a/4b. Here, the two sub-regions interlock in a comb-like manner (in other words, interdigitally) and are arranged along the entire length of the respective passive resistive element. Similarly, such an embodiment can also be implemented for electrodes facing the cover wafer and/or the bottom wafer.

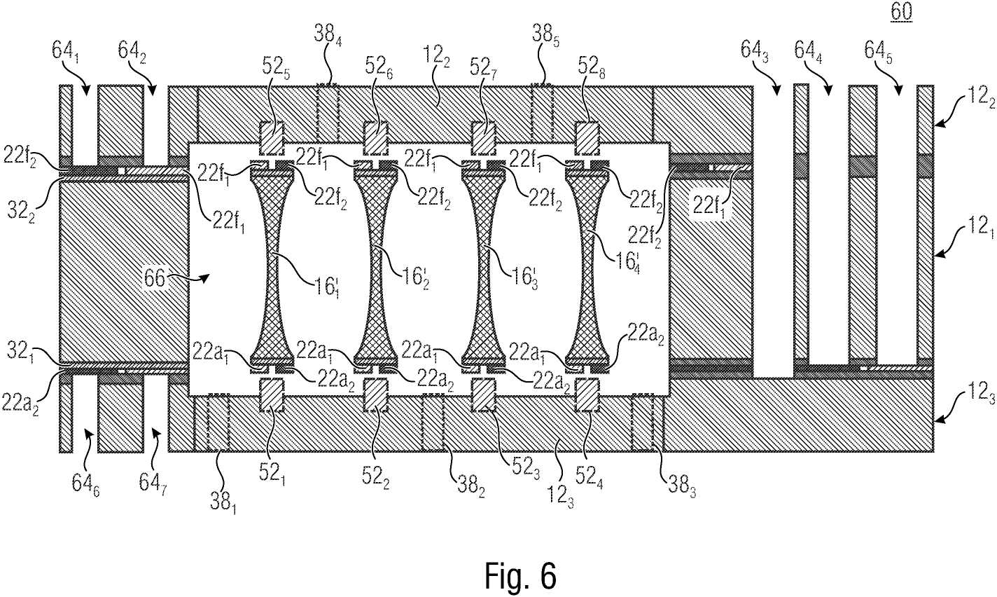

FIG. 6 shows a schematic side sectional view of a part of a MEMS device 60 according to an embodiment. There, in addition to the cavity 66, which is subdivided into sub-cavities by means of four movable elements 16′₁ to 16′₄, outer regions in which the interconnection of the electrodes is illustrated in more detail are also shown. Recesses 64₁ to 64₇ can expose electrodes and/or other regions so that they are ready for contacting. As shown with reference to the recesses 64₁ to 64₅, this may be done so that all electrodes along one side of MEMS device 60 are accessible.

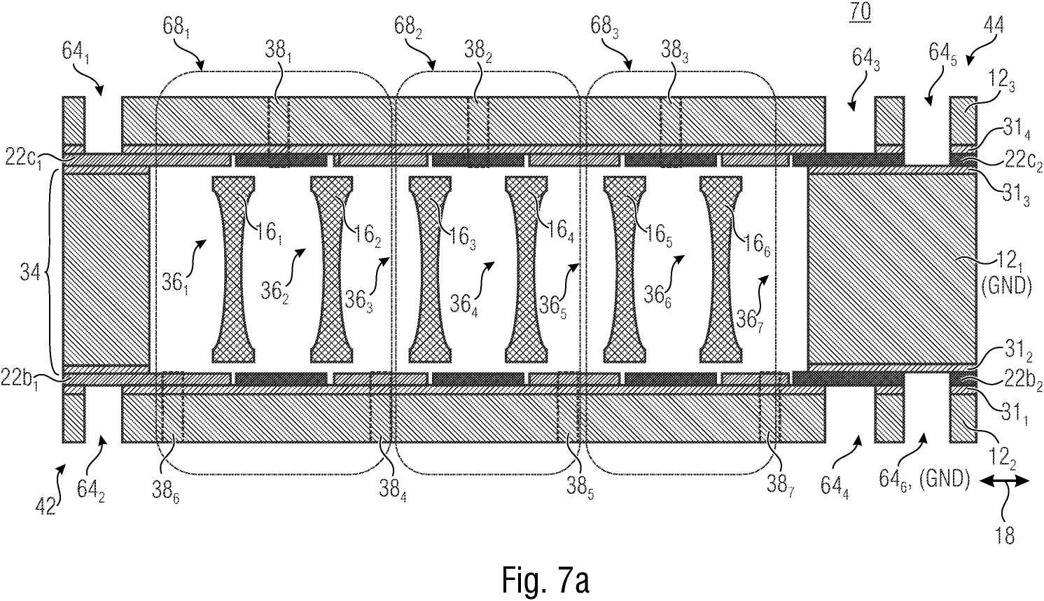

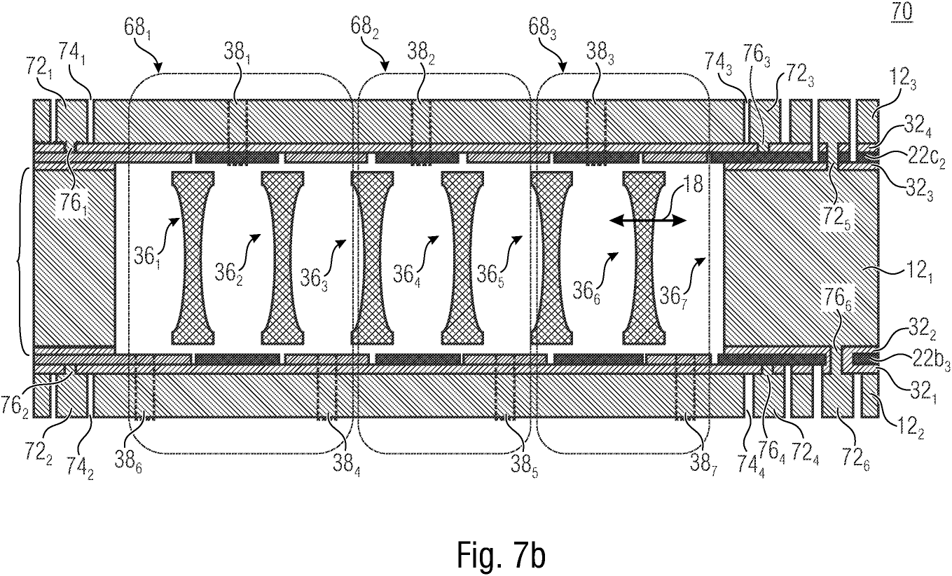

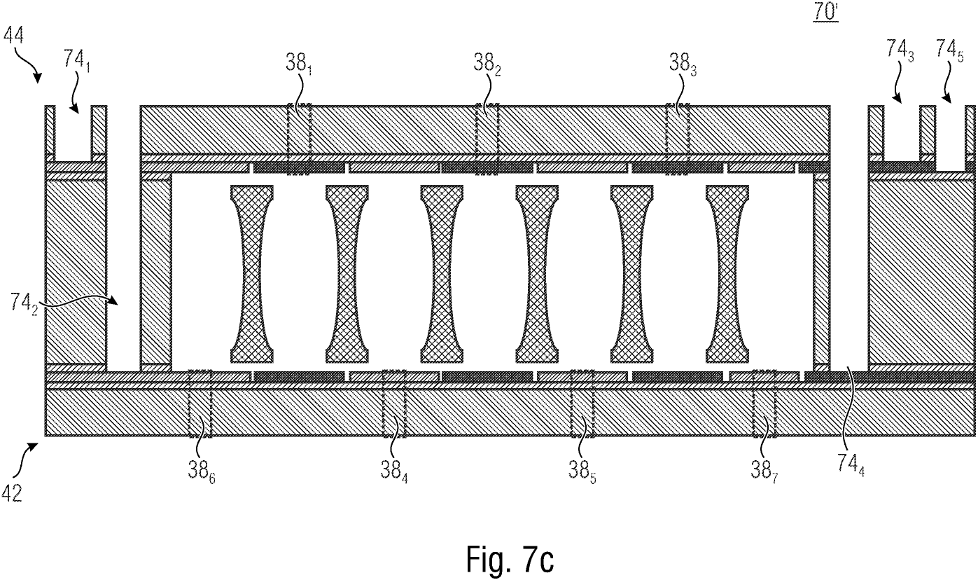

FIG. 7a shows a schematic side sectional view of a MEMS device 70 according to an embodiment. For example, the MEMS device 70 comprises a configuration as described in connection with the MEMS device 20. Any two adjacent movable elements 16₁ and 16₂, 16₃ and 16₄, and 16₅ and 16₆, respectively, may form an elementary cell 68₁, 68₂, and 68₃, respectively, of the MEMS device 70. While openings 38₁, 38₂ and 38₃ of the wafer 44 may be exclusively associated with the elementary cells 68₁, 68₂ and 68₃ for example, openings 38₄ and 38₅ of wafer 42 may be shared by adjacent elementary cells 68₁ and 68₂, and 68₂ and 68₃, respectively.

Recesses 64₁, 64₂, 64₃ and 64₄ for contacting the electrodes 22_{C1}, 22_{C2}, 22b₁ and 22b₂, respectively, may be provided in the substrate layers 12₂ and 12₃. Alternatively or additionally, recesses 64₅ and/or 64₆ for locally exposing the layer 12₁ to connect it to a potential, for example a reference potential (ground GND), may be provided.

In other words, FIG. 7a shows a cross-sectional view of an embodiment of a MEMS-based transducer with linear deflection behavior with 3 adjacently arranged elementary cells. The structure is shown with passively deflectable resistive elements. Thus, the electrically conductive layers are each connected to the bottom and cover wafers via an electrically insulating layer. The elementary cells are connected to each other via cavities of adjacent passive deflectable resistive elements. In addition, the positions of possible lower and upper outlet openings in the bottom and cover wafers are shown. Regions 64 for electrically contacting the sub-layers are provided. Similarly, regions for electrically contacting the sub-layers of further electrodes are provided. The contacting regions are shown as openings etched, for example as holes or square recesses or rectangular grooves, down to the respective electrically conductive layers. The embodiment is not limited to the location of the electrically conductive layers shown. In order to establish a potential difference between the layers 22b and 22c and the passively deflectable elements, contacting with GND in the layer 12₁ is possible. Similarly, a structure with actively deflectable elements according to FIG. 3a to FIG. 4b is possible.

Contacting the chip in FIG. 7a will take place, for example, by wire bonding. Because the contact holes are placed on both sides of the chip, the wire bonding process must also take place from 2 sides.

FIG. 7b shows a schematic side sectional view of MEMS device 70 in an embodiment, in which electrically conductive elements 72₁ to 72₆ are arranged in recesses 64₁ of FIG. 7a to enable contacting of the corresponding regions.

The electrically conductive regions or elements 72₁ to 72₆ may be spaced apart from the surrounding material by gaps 74₁ to 74₄, wherein said gaps may optionally be filled with electrically insulating material. By electrically insulating connection layers 32, electrically conductive structures 76, for example made of the material of the electrically conductive elements 72 or of another electrically conductive material, which may be enclosed by the material of the connection layers 32 or the electrically insulating property thereof in the region of surrounding electrodes may be arranged in order to avoid short circuits. Here, the element 72₅ may provide contacting between the layer 12₁ and a sub-region of the layer 12₃ as also shown the element 72₆. In this regard, the element 72₅ may also be electrically insulated from other elements, such as sub-regions of the electrically conductive layer 22c. Contacting may be provided on both sides at this point.

In other words, FIG. 7b shows a transducer with linear deflection behavior and an alternative structure of a MEMS-based transducer that differs with respect to the contacting as well as 101 the electrically conductive layers. In this case, the contacts to the layers are not made by recesses. Alternatively, the layers are connected to the cover and bottom wafers by vias through conductive elements. The layer 12₁ is connected to the bottom or cover wafer by the conductive plugs. The separation of the electrical potentials in the cover or bottom wafers are made by the separators (or recesses). The advantage of this embodiment is that the contacting of the layers does not take place in the recesses, but on the surface of the bottom or cover wafers.

FIG. 7c shows a schematic side sectional view of a MEMS device 70′ similar thereto, in which the contacting is done by means of recesses 74₁ to 74₅ from one side only, the side of the wafer 44, for example a cover wafer. Accepting the comparatively deep trenches, a simple placement of the MEMS device 70 on a substrate can be carried out, since the electrical interconnection from one side may be sufficient.

In other words, when the conductive layers are placed on the resistive elements, contacting the electrodes can take place in a variety of ways. Contacting the electrodes may be done from two sides or from one side only. In still other words, FIG. 7c shows a transducer with linear deflection behavior: It is similar to FIG. 3a, except that the contacting takes place from one side of the chip. That is, all electrodes used for actuation are accessible (through the recesses) from one side of the chip. In this case, wire bonding of the finished chip is easier to implement because the chip can be wire bonded from one side only.

Analogous to the contacting options shown in FIG. 7a, the drive alternative in FIG. 3a can also be contacted.

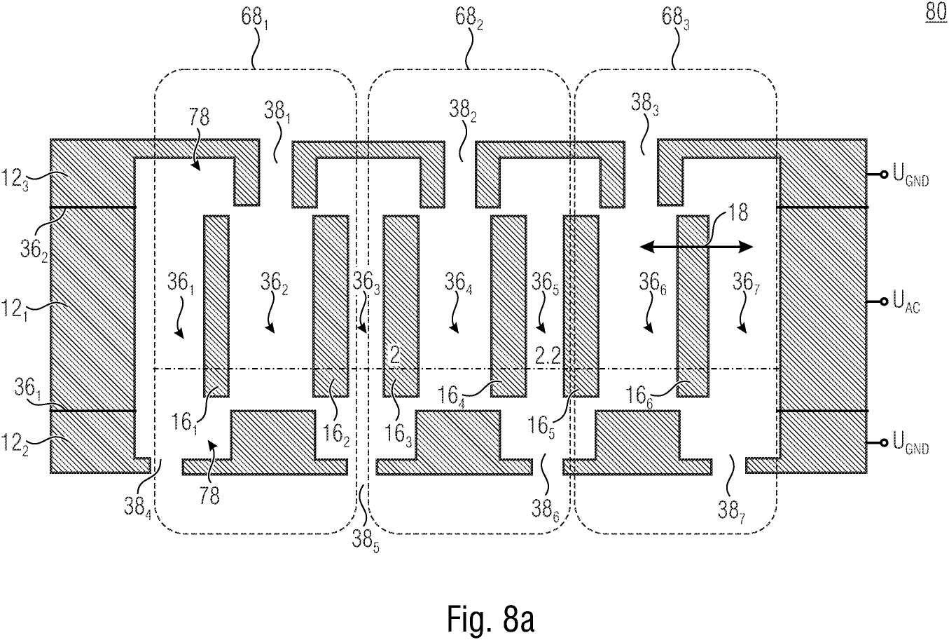

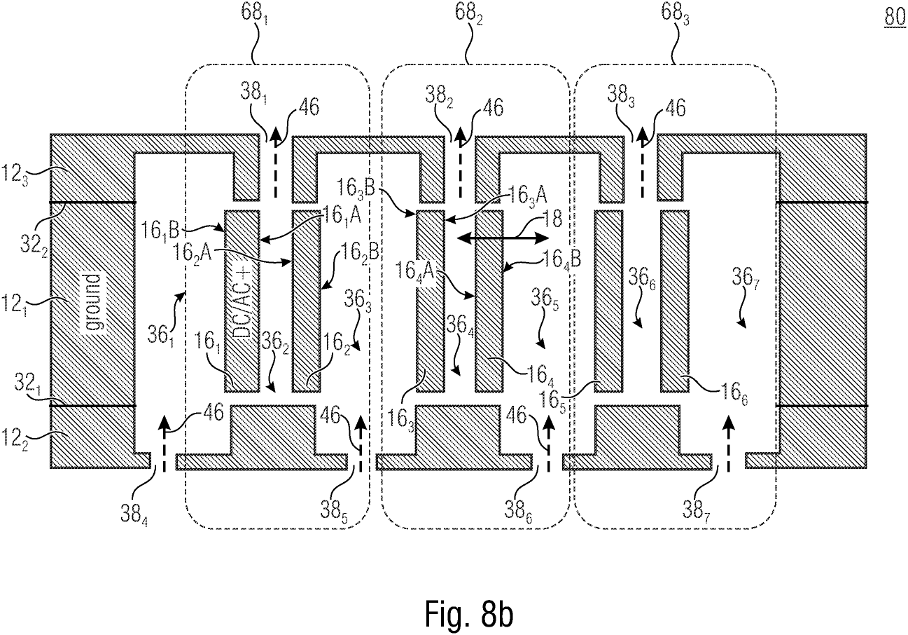

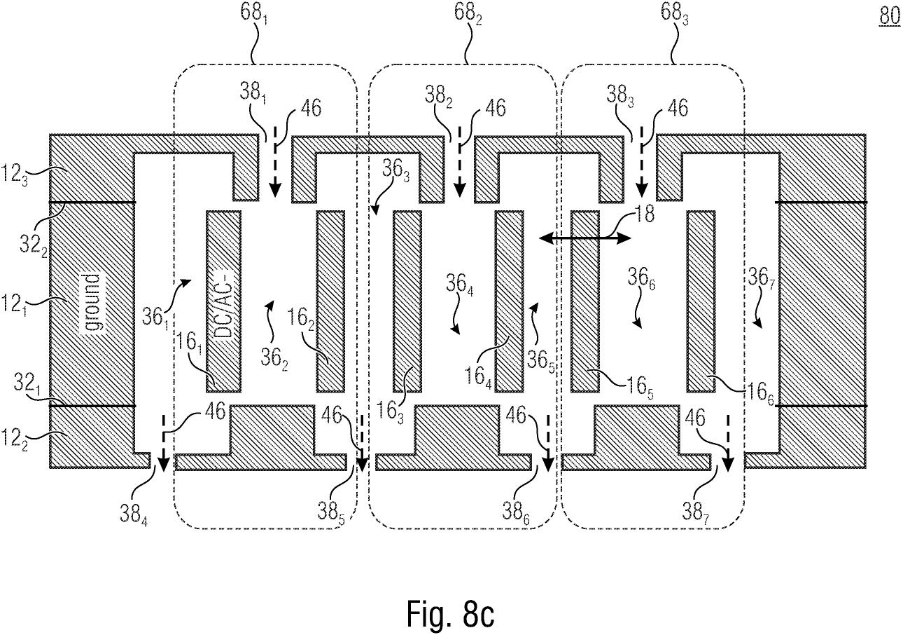

FIG. 8a shows a schematic side sectional view of a MEMS device 80 according to an embodiment, in which the sub-cavities 36₁ to 36₇ extend locally into at least one of the layers 12₂ and 12₃ by providing recesses 78 therein, for example between adjacent openings 38₁ and 38₂, 38₂ and 38₃ and/or in the region of the openings 38₄, 38₅, 38₆ and/or 38₇.

Exemplarily, the layer 12₁ may be connectable to an alternating potential U_{AC}, orU_{AC} or +U_{AC}, so that this potential may also be applied to the movable elements 16₁ to 16₆. In contrast, the layers 12₂ and 12₃ may be connectable to a reference potential GND.

FIG. 8b shows a schematic side view of the MEMS device 80 of FIG. 8a with a slightly different configuration, in which, although the movable elements are connectable individually or in groups to a voltage DC or AC+, as described in connection with FIG. 8a, the surrounding substrate of the layer 12₁ is connected to the reference potential, which may allow easy and safe handling of the MEMS device. Optionally, instead of configuring the substrate for connection to the reference potential, electrical insulation may be provided on the MEMS device 80. FIG. 8b shows the MEMS device 80 in a state in which the movable elements 16₁ to 16₆ have moved towards each other in pairs within the elementary cells 68₁, 68₂ and 68₃ such that respective main sides 16₁A and 16₂A and 16₃A and 16₄A, respectively, defining sub-cavities 36₂ and 36₄ are moved towards each other.

FIG. 8c shows a schematic side sectional view of the MEMS device 80 of FIG. 8b in a complementary state in which the movable elements 16₁ and 16₂, 16₃ and 16₄, and 16₅ and 16₆, respectively, of a respective element cell 68₁, 68₂, 68₃ are moved away from each other to create a reverse fluid flow.

In other words, FIGS. 8a to 8c show transducers with non-linear deflection behavior: FIGS. 8a-c show a structure of a MEMS-based sound transducer in three deflection states. Similarly, a simplified structure with two electrodes is shown. Here, the layers of the cover wafers 12₃ and the bottom wafers 12₄ form a first electrode and the layer of the device wafer, or the passively deflectable resistive elements, forms a second electrode. The resistive elements are shown in simplified form in this embodiment and may have other cross-sections, such as those described herein. The resistive elements are arranged in a cavity machined out of the layer 12₁ by etching processes and through further layers which are the top and bottom wafers. At least one end, advantageously two opposite ends, are connected to the substrate of the layer 12₁. Advantageously, the layers have cover and bottom wafer structures that result in a large volume of the cavity. The layers are connected to the layer 12₁ via an insulating layer 32₁/32₂.

The resistive elements have main sides. Main sides are characterized in that they are arranged opposite each other in the case of adjacent resistive elements and delimit a sub-cavity 36₂, 36₄ and 36₆ connected to the upper outlet opening 38₁-38₃. Accordingly, the opposite sides of the resistive elements are characterized in that they enclose cavities 36₁, 36₃, 36₅ and 36₇ simultaneously connected to the lower outlet openings 38₄-38₇. Moreover, the opposite sides of the resistive elements are characterized in that they delimit the sub-cavities 36₁, 36₃, 36₅ and 36₇ connecting the elementary cells to each other.

FIG. 8a shows the resistive elements in an undeflected state.

FIG. 8b shows the resistive elements in a deflected state in a first time interval at an additionally applied voltage (combination between DC and AC) between 0 and 100 V, advantageously between 1 and 50 V, particularly advantageously between 1 and 25 V, approximately 24 V. Here, the resistive elements deflect along the direction of movement 18. Adjacent resistive elements of an elementary cell move towards each other so that the distance between the respective main sides decreases and the volume of the sub-cavities 36₂, 36₄, 36₆ decreases therefore as well. As the volume of the sub-cavities is reduced, fluid is discharged from the sub-cavities through the outlet openings 38₁-38₃. In the same time interval, the opposing sides of the resistive elements move in one direction so that the distances between the opposing sides are increased. Similarly, the volume of the cavities 36₁, 36₃, 36₅, 36₇ enclosed thereby is also increased. The volume flow generated through this conveys fluid through the openings 38₄-38₇ into the sub-cavities.

FIG. 8c shows the resistive elements in a deflected state in a second time interval that directly follows the first time interval. Over a long period of time, the first and second time intervals alternate in this order so that pressure pulses are emitted, for example as sound waves.

In the second time interval, the resistive elements are supplied with a different voltage (DC+AC) whose phase is shifted by, e.g., 180° compared to the voltage in the first time interval, wherein other phase angles are also adjustable. The shift of the phases can also assume other values greater than zero. Thus, the resistive elements move along the movement direction 18 in a direction opposite to the direction in the first time interval. In other words, the distance between the opposite sides of adjacent resistive elements decreases, thereby increasing the volume of the sub-cavities 36₂, 36₄, 36₆ and, as a result, a volumetric flow of fluid is transported into the sub-cavities through the openings 38₁-38₃. Similarly, the distance between the opposite sides of adjacent resistive elements decreases so that a volumetric flow of fluid is conveyed out of the sub-cavities 36 ₁, 36₃, 36₅ and 36₇ through the openings 38₄-38₇.

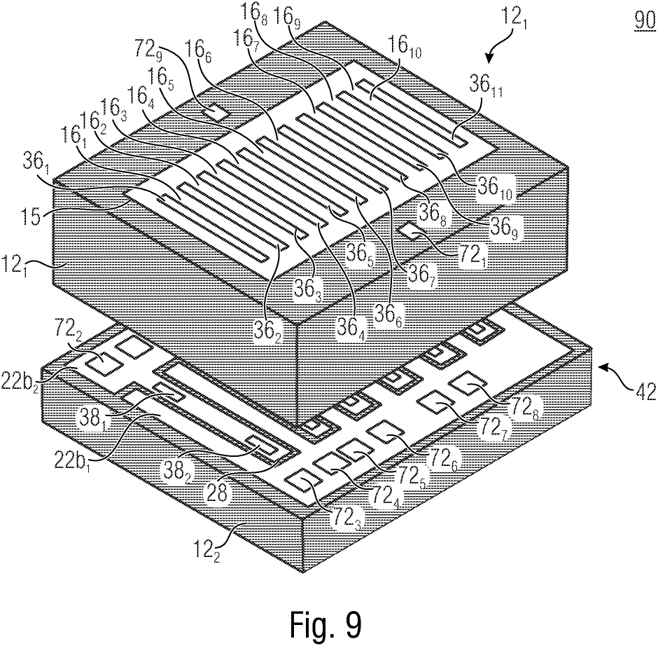

FIG. 9 shows a schematic perspective view of portions of a MEMS device 90 according to an embodiment, for example in the form of the wafers 42 as well as the layer 12₁. As an example, 10 movable elements 16₁ to 16₆ that may be surrounded by sub-cavities 36₁ to 36₁₁ are shown. Reference numeral 15 shows a step, chamfer, or rounding that recesses or reduces in height an inner region of the movable elements 16 relative to a surrounding region of the remainder of the layer 12₁ so that mechanical contact with the movable elements 16 does not take place during subsequent bonding processes, such as for arranging the wafer 44.

In other words, FIG. 9 shows a perspective view of a MEMS-based sound transducer. The layers containing the passive resistive elements, and the layer (bottom wafer) connected to the layers 22b₁/22b₂ are shown. The layer comprising the cover wafer is not shown. Similarly, the implementation of layers 22b₁ and 22b₂ interlocking in a finger-like manner and thus being arranged adjacent to each other in the region of the deflectable passive elements is shown. The layers 22b₁/22b₂ are electrically separated by the region 28 constituting an electrical insulation. In this regard, the layers 12₂ and 12₁ have thicknesses that differ from each other. For example, the layer 12₂ comprises a thickness of 400 µm. For example, the thickness of the layer 12₁ may have values between 400 µm and 5 mm. The contacts in the layer 12₁ that, together with further contacts in the layer not shown, connect the control to the electrically conductive layers 22b₁/22b₂ are shown with 72ᵢ. The control signals are then distributed to the zones of the respective regions of the layers 22b₁ and 22b₂ by means of suitable contacts 72.

Another aspect of this embodiment are the arrangements of the openings 38. In this embodiment, these openings connect the cavities 36 (in other words, trenches or recesses) to the surrounding fluid. These openings are shown as rectangular in this embodiment. In this embodiment, the respective cavities 36 are connected to two openings, each of which is discretely spaced apart. Similarly, however, it is also possible for an opening to occupy a length across the entire length of the passive resistive element or a length that differs therefrom. Similarly, the embodiments are also not limited to a rectangular shape. Further shapes that deviate from a rectangular shape are part of embodiments, which shall only be mentioned here.

By the reference numeral 15, reference is made to a surrounding step or chamfer or rounding arranged between the layer 12₁ and the substrate of the resistive elements. With a height difference of about 100 nm, the substrate of the resistive elements is slightly recessed with respect to the substrate 12₁ to prevent the resistive elements from being strained during the used bonding process of the cover layer. Similarly, the step may also be provided in the region of the bonding zone of the layer 12₂.

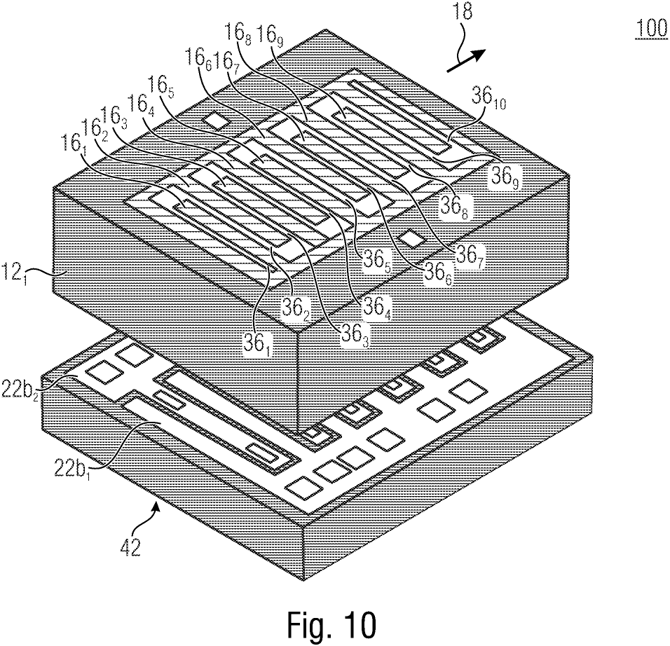

FIG. 10 shows a schematic perspective view of a MEMS device 100 according to an embodiment. Compared to other embodiments described herein, the movable elements 16₁ to 19₉ are elements firmly clamped on one side only, wherein, as an example, movable elements adjacent to each other are firmly clamped on opposite sides and may be arranged in the sense of interdigital elements. That is, embodiments described herein are not limited to movable elements clamped on both sides.

In other words, FIG. 10 shows another embodiment of a MEMS-based sound transducer 100 comprising deflectable resistive elements 16₁ to 16₉ connected on one side to the surrounding substrate of the layer 12₁, wherein a number of the resistive elements may again be arbitrarily configured here.

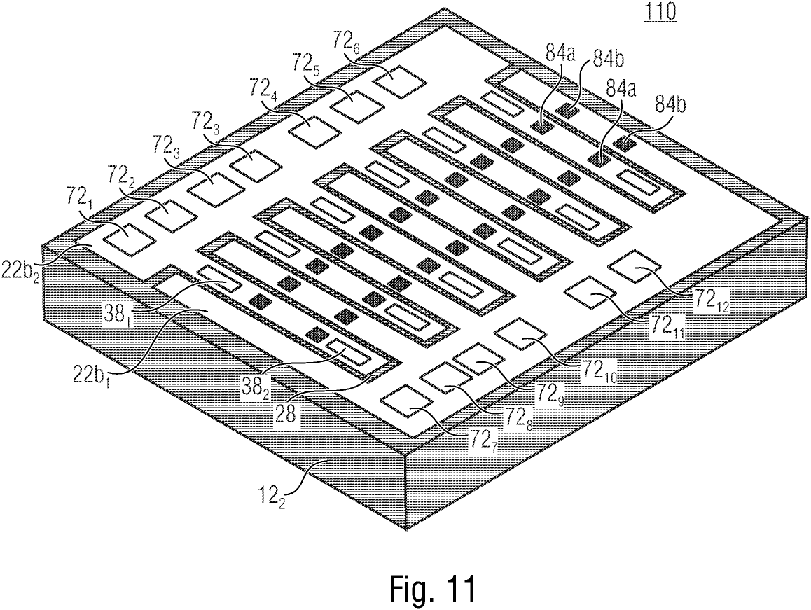

FIG. 11 shows a schematic perspective view of a MEMS device 110 according to an embodiment, or a part thereof, namely the layer 12₂, which may comprise openings 38 as well as interdigital electrodes 22b₁ and 22b₂, which may comprise contacts 72₁ to 72₁₂ that may pierce the electrodes 22b₁ and 22b₂, for example, as exemplarily explained in connection with FIG. 7b.

Furthermore, spacers 84a and/or 84b that may limit a distance, in particular a minimum distance, between the movable element sweeping over the layer 12₂ and the movable element itself may be provided. The spacers may be formed of electrically insulating material, for example, and may prevent a cover wafer and/or a bottom wafer from being bonded to the fin over a large area during the wafer-level bonding, since their dimensions are relatively small, in the range of a few micrometers. The spacers may be used as a transport fuse. For example, spacers 84a and/or 84b may be removed, for example, in a particular hydrofluoric acid combination, such as HF gas-phase etching (GPE) prior to first operation of the chip.

Spacers are optional and may be also provided on a part of the movable elements only.

In other words, FIG. 11 shows a perspective view of the layer 12₂ of a MEMS-based sound transducer and concretizes the implementation of the description of FIG. 9.

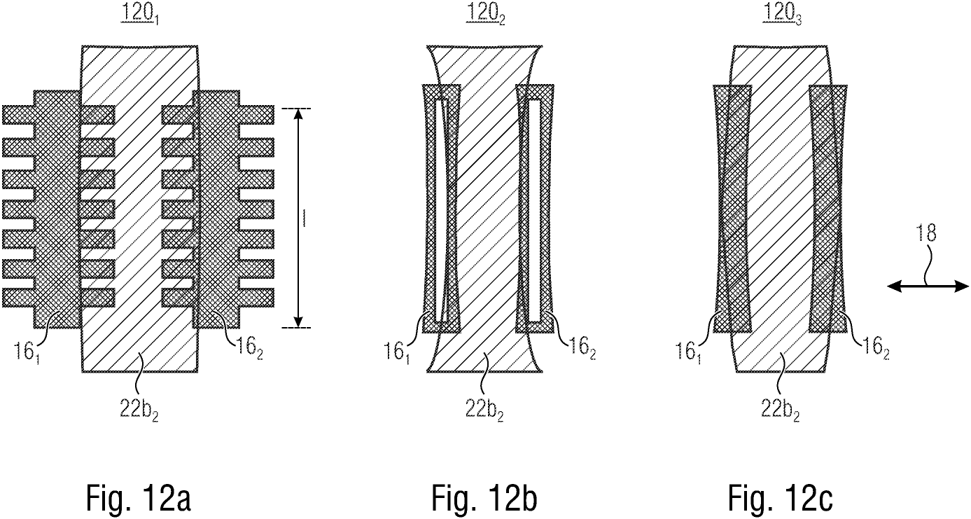

FIG. 12a shows a schematic top view of portions of a MEMS device 120₁ according to an embodiment. Exemplarily, the electrode 22b₂ is rectangular in shape and is arranged approximately centrally across a space between two adjacent movable elements 16₁ and 16₂, as also shown, for example, in FIG. 2a. For example, the movable elements 16₁ and 16₂ may be formed in a comb shape.

FIG. 12b shows a schematic top view of parts of a MEMS device 120₂, in which the movable elements 16₁ and 16₂ may be formed as hollow bodies, for example, which allows material savings. Independently thereof, for example, the electrode 22b₂ may be configured to be concave.

FIG. 12c shows a schematic top view of parts of a MEMS device 120₃, in which the movable elements 16₁ and 16₂ are formed as solid bodies and, independently, the electrode 22b₂ is formed as a convex shape. The different details of FIGS. 12a, 12b and 12c can be readily combined. That is, the electrodes of the drive structures arranged on the substrate may have a constant or variable lateral dimension along an axial path perpendicular to the layer stack direction, i.e. parallel to the plane direction 18. The same applies to the electrodes on the movable elements or in the movable elements.

In other words, FIGS. 12a-12c show in a top view of a region of an alternative elementary cell showing various embodiments of the deflectable resistive elements. In this regard, FIG. 12a shows a comb-shaped implementation. FIG. 12b shows a concave implementation of the deflectable resistive element and the layer 22b₂ illustrated exemplarily. Further, it is shown that the resistive elements may be thin-walled bodies having no material in the area of the centroid fiber. In contrast, FIG. 12c shows a convexly configured form of the illustrated components of the elementary cell. Advantageously, these implementations will be used when, for example, a certain force is used during deflection and the stiffness of the resistive elements must be optimized (e.g. minimized). Or there are increased requirements for a transition between the resistive element and the surrounding substrate that is as stress-free as possible, so that a widening of the resistive element in the region of the transition is useful. Similarly, the shape of the deflection of a resistive element can be influenced. It will be understood by a person skilled in the art that a hollow resistive element comprises a greater light weight character than a filled resistive element. Thus, the performance of a transducer can be directly influenced by the geometric design of the resistive elements. It is undeniable that various implementations can also be combined in a MEMS transducer.

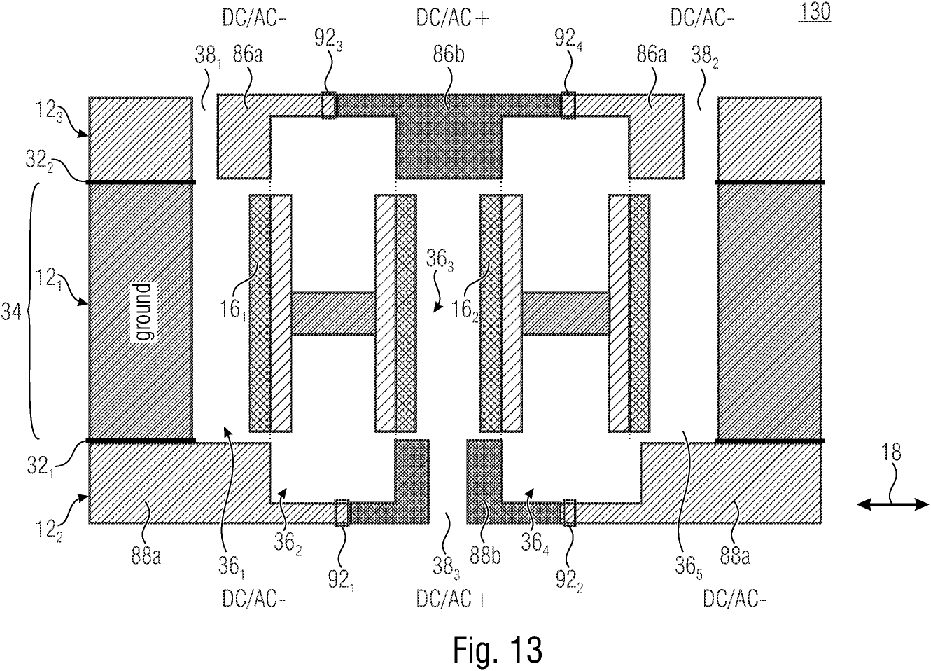

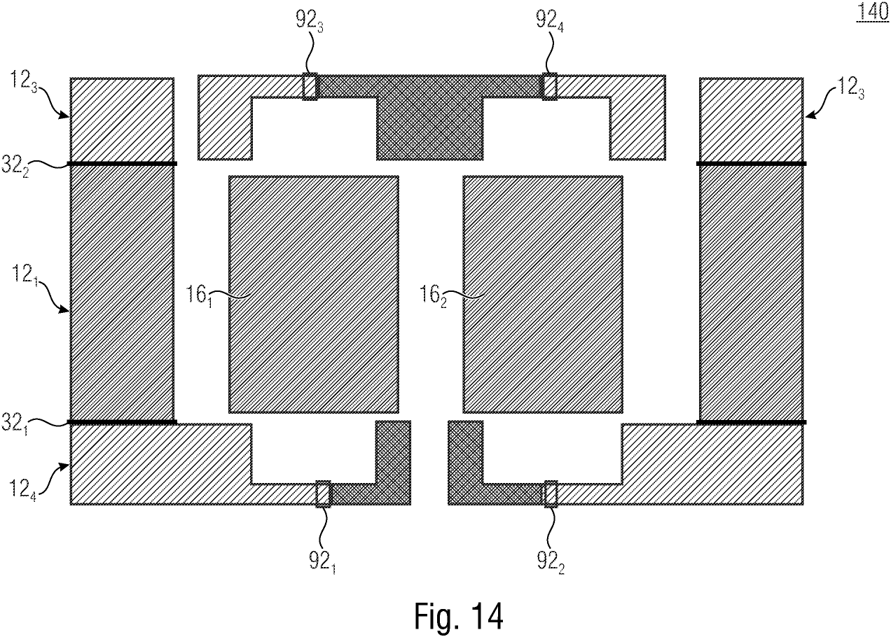

FIG. 13 shows a schematic side sectional view of parts of a MEMS device 130 according to an embodiment. There, for example, the layer 12₂ and/or the layer 12₃ is formed to be electrically conductive and is divided by means of electrically insulating elements or regions, or segmentations, 92 into different segments or regions to which different potentials 86a/86b and 88a/88b, respectively, can be applied, while a reference potential can be applied to the layer 12₁ with exemplary H-shaped movable elements 16₁ and 16₂. For example, the potential 86a may be AC- and the potential 86b may be AC+ and/or a DC potential may be alternately applied to different segments. The same applies to the potentials 88a/88b.

In other words, FIG. 13 shows a resistive element with linear deflection behavior. Here, FIG. 13 shows another embodiment according to FIGS. 8a-c. What is different is the H-shaped implementation of the resistive elements and the double potential guidance in the cover and bottom wafers, respectively.

Resistive element with linear deflection behavior: This means that electrical forces are generated upon application of a voltage 12₁; 86, 88. When the voltages 86a/86b and 88a/88b, respectively, are equal, an equilibrium between the forces occurs and the resistive element does not move. However, if the voltage between 86a/86b or 88a/88b become different, an imbalance occurs and the resistive element moves linearly in one direction. If the voltage between 86a/86b or 88a/88b is reversed, the resistive element moves linearly in the opposite direction. Advantageously, this results in a very large volume of the surrounding cavity, which allows a large sound pressure level of the resulting transducer. However, this also entails a large force with a large deflection of the resistive elements. For this reason, this design allows a linear relationship between the deflection force to be applied and the applied voltage.

FIG. 14 shows a schematic side sectional view of a MEMS device 140 according to an embodiment, which may be in accordance with the MEMS device 130. However, unlike the MEMS device 130, the MEMS device 140 may include block-shaped or solid movable elements 16₁ and 16₂.

In other words, FIG. 14 shows a resistive element with linear deflection behavior, FIG. 14 thereby concretizes FIG. 13 with solid resistive elements.

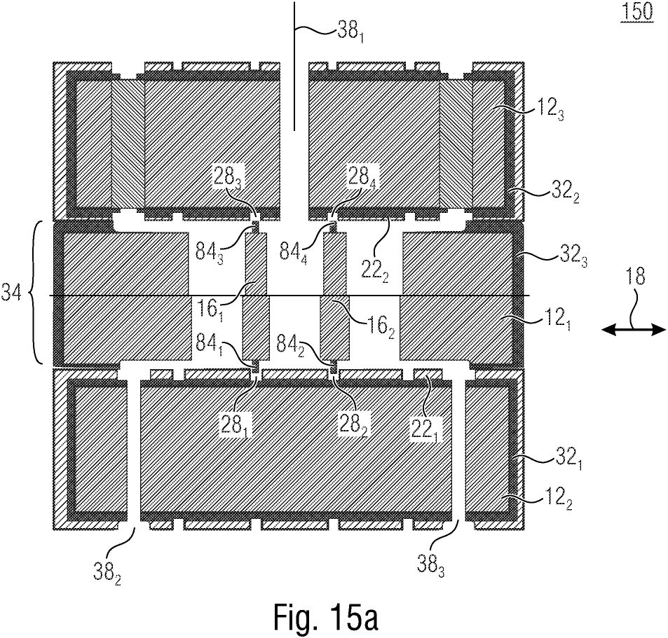

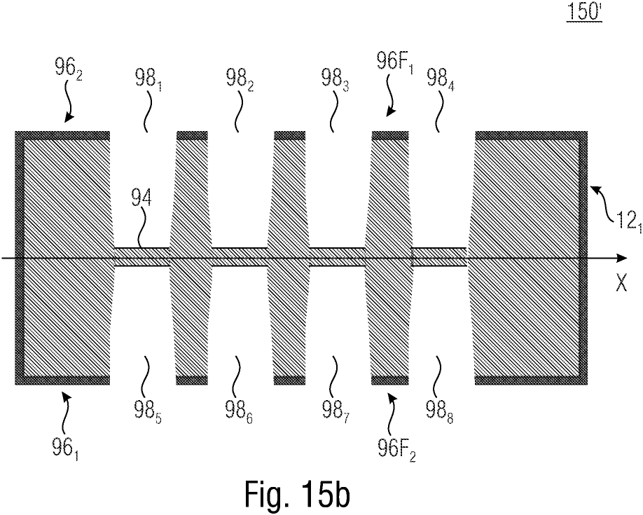

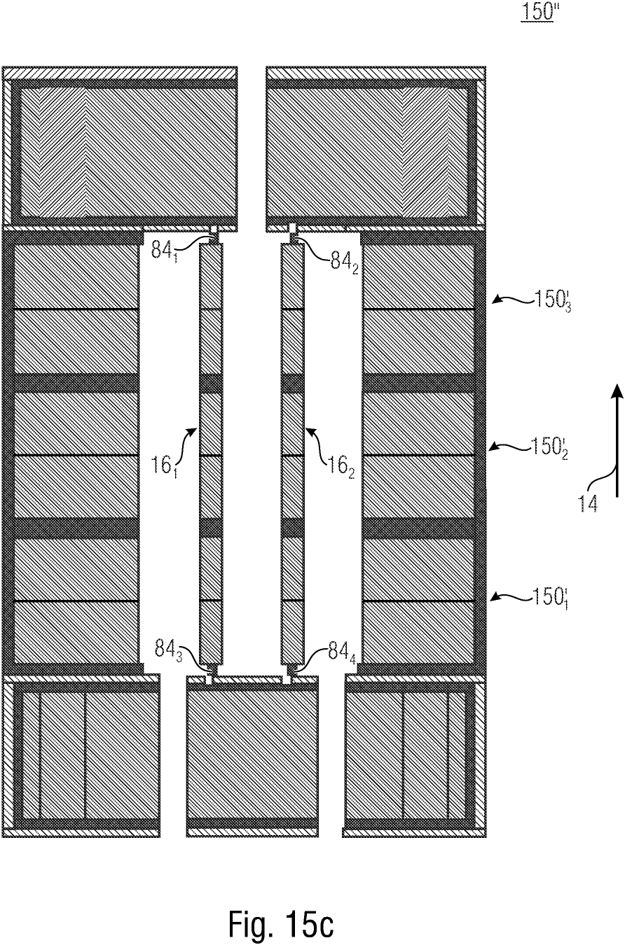

FIG. 15a shows a schematic side sectional view of a MEMS 150 according to an embodiment, in which the insulating layers 32₁ and 32₂, same as exemplary electrode layers 22₁ and 22₂, are formed circumferentially around the layers 12₂ and 12₃, as is an electrically insulating layer 32₃ around the layer 12₁. This may enable simple wafer bonding.

In other words, FIG. 15a shows in a cross-sectional view an embodiment of a MEMS-based sound transducer. This embodiment shows the MEMS sound transducer in a method step of its fabrication. Here, it can be seen that spacers 84 are connected to both sides of the resistive elements in the perpendicular direction. These spacers represent force dissipation points that make it possible to realize a uniform bonding of the layers 12₁. In a further step in the manufacturing process, these spacers are then removed. Similarly, it is conceivable that these spacers are at the same time a transport safeguard allowing damage-free transport during the manufacturing process. It is conceivable that these spacers are also only destroyed when a signal is first applied, thus providing a transport safeguard throughout the B2B process. Since there are many such spacers on the chip, it is possible to design them with different sizes so that when the spacers are removed, only some are selectively removed and others still remain: the smaller spacers are removed and the larger ones remain. This would make it possible to selectively release or move only certain resistive elements. In this way, one could use or release the same chip for different applications (with more or less free resistive elements).

FIG. 15b shows a schematic side view of an intermediate product 150′ for a MEMS device according to embodiments described herein. It shows that material 94 remains in a center region when etching is performed from a first side 96₁ and a second side 96₂ to form depressions 98₁ to 98₈. Once the etching has progressed such that the opposing depressions meet and the material 94 is released, movable elements may be released through this. For example, the intermediate product 150′ may also be an already bonded wafer specimen and/or a high-thickness wafer in which twice an aspect ratio is producible due to the etching on both sides.

FIG. 15b shows in a sectional view an embodiment of a transducer. This illustration is not intended to claim a method of fabricating a MEMS. Rather, it shows the advantage of such a structure as claimed by the device. An important aspect of the present invention is that the resistive elements must be symmetrical in design to ensure uniform deformation during the motion process. A non-symmetrical design will result in the non-uniform deformation behavior that was just described. As a result, there would no longer be a linear relationship between the applied voltage and the deflection of the resistive element, resulting in a high distortion factor. An asymmetrical structure results from the method used in the etching process. By machining out material to form recesses, trenches, or cavities, there are no parallel edges, but always funnel-like recesses. The width of the recess is always smaller at its bottom than at its top.

The etching direction and the subsequent connection of wafers thus significantly determine the formation of the resistive elements.

Similarly, FIG. 15b illustrates that stacking of resistive elements is possible to increase the resulting aspect ratio of the transducer element without the constraints imposed by the applied Bosch method.

It illustrates that the device wafer etching has taken place from 2 sides (front and back) to increase the aspect ratio of the resistive elements, wherein:
· 98₁-98₄ show a layer with an etching direction from the front;
· 98₅-98₈ show a layer with an etching direction from the back side,
· layer 94 is only illustrated schematically to show that the etchings will eventually meet; 94 is no longer present in the final product.

The advantages of etching from 2 sides:
the fins are symmetrical relative to the plane spanned by the first and second directions. Thus, the areas 96F₁ and 96F₂ shown are equal and the electrical forces to be applied to deflect the resistive elements in the movement direction are equal. A uniform deflection by the same amount is thus ensured.

If both layers are etched from only one side, the surfaces 96F₁ and 96F₂ are not evenly configured or they even deviate from each other in their surface area. This would result in an uneven deflection of the resistive elements.
Doubling the aspect ratio of the recesses (in other words, of the trenches) to 60. By stacking the resistive elements, the resulting transducer elements are no longer limited to the Bosch method.

FIG. 15c shows a schematic side sectional view of a portion of a MEMS device 150″ according to an embodiment. In this regard, the movable elements 16₁ and 16₂ may be obtained, by way of example, by stacking structures similar to the intermediate product 150′ by stacking a plurality of such intermediate products, such as by wafer bonding. It should be noted that FIG. 15c shows only two of the three movable elements obtainable in FIG. 15b. By increasing the aspect ratio accordingly by joining them along the plane direction 14, an increase in the efficiency obtainable, for example, by means of a loudspeaker configuration of the MEMS device can be obtained, for example, since the sound pressure level (SPL) is increased accordingly. Furthermore, stacking along the layer stack direction 14 enables a high stiffness along this direction, which may lead to a lower susceptibility to so-called for so-called pull-in effects and thus may lead to a lower holding force or a lower vertical deflection parallel to the layer stack direction 14, which is advantageous. Thus, a structure in which the movable element comprises a plurality of layers connected by means of a bonding process is shown.

To increase the SPL, it is possible, as shown in FIG. 15c, to connect several layers. In this way, the aspect ratio of the trenches, or resistive elements, can theoretically be greatly increased. Here, the “continuity” of the device layer is advantageous compared to the used support layers reported in the known technology (e.g. handle wafers in BSOI wafers).

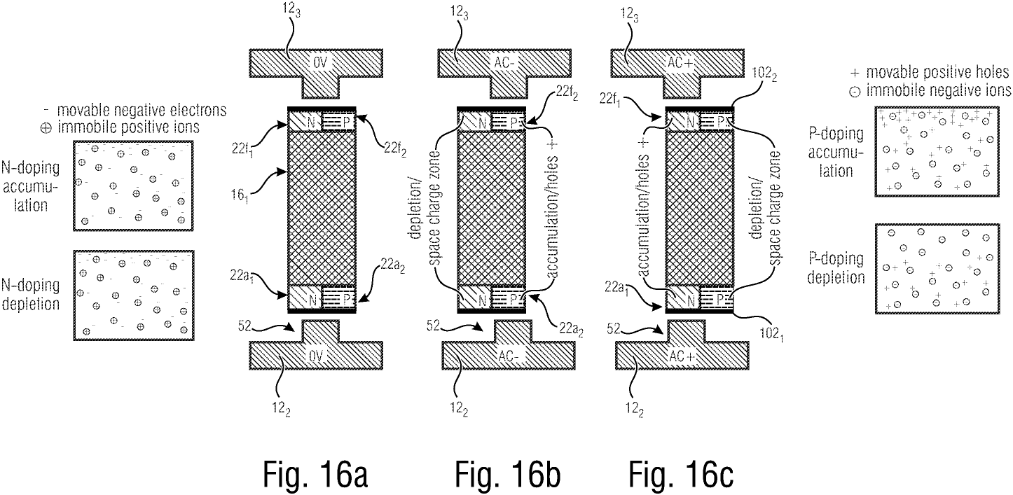

Based on FIGS. 16a, 16b and 16c, a configuration in which the electrodes on the movable element can be obtained by means of N-doping in the electrodes 22a₁ and 22f₁ or by means of p-doping in the electrodes 22a₂ and 22f₂ is illustrated. When the layers 12₂ and/or 12₃, possibly with local reduction of the distance, are connected to a reference potential, such as 0V, GND, a reference position can be obtained. When a negative voltage is applied to the layers 12₂ and 12₃, a force can be applied to the movable element 16 due to the accumulation of movable positive holes in the regions 22f₂ and 22a₂, which leads the electrodes 22a₂ and 22f₂ into a range of a small distance to an external negative voltage (AC-). In FIG. 16c, a complementary configuration in which, due to a positive voltage on the layers 12₂ and 12₃, the high number of movable negative electrodes accumulated in the regions 22₁ and 22a₁ are moved toward the surface topography 52 is shown.

An accumulation of a movable negative electron can also correspond to a depletion of an immovable positive ion and vice versa. Due to a depletion next to an accumulation, a space charge zone can be created.

Electrically insulating layers 102₁ and 102₂, e.g. including silicon nitride or silicon oxide, may be arranged to neutralize the surface states and to maintain a most neutral state of the movable element 16.

FIGS. 16a-c each show an alternative drive with linear deflection behavior and based on a cover drive. Advantageously, this configuration can improve the usual linear structure which provides three electrodes. All three illustrations essentially disclose that a layer is connected to the deflectable member, said layer containing N-doped and P-doped regions arranged adjacent to each other and each connected to the deflectable member. The layers are cover and bottom wafers providing a protrusion 52 in the deflectable element region. These protrusions are integrally connected to the cover and bottom wafers and have a minimum distance from the deflectable element, so that an acoustic short circuit between the sub-cavities adjacent to the deflectable element is prevented. FIG. 16a shows the device in an undeflected state in which no voltage is applied.

FIG. 16b shows the alternative drive in a first deflection state. The deflection of the deflectable element is based on the field effect. In the figure, the deflection is shown in a first direction. The deflection is based on a negative voltage AC- being applied to the cover and base wafers. Due to the field effect, an accumulation of charge carriers (moving holes/+ directly at the interface to the oxide, depth of 10-20 nm) occurs in the P region. This is accompanied by a depleted zone in the N region (immovable ions/-, depth of 1-2 µm). The largest capacitance change, which is equivalent to the deflection force, occurs when the fin overlaps with the cover in the P region.

FIG. 16c shows the alternative drive in a second deflection state. The deflection of the deflectable element is based on the field effect. In the figure, the deflection is shown in a second direction. The deflection is based on a positive voltage AC+ being applied to the cover and base wafers. Due to the field effect, an accumulation of charge carriers occurs in the N region of the layers (moving holes/+ directly at the interface to the oxide, depth of 10-20 nm). This is accompanied by a depleted zone in the P region of the layers (immovable ions/-, depth of 1-2 µm). The largest capacitance change, which is equivalent to the deflection force, occurs when the fin overlaps with the cover in the P region.

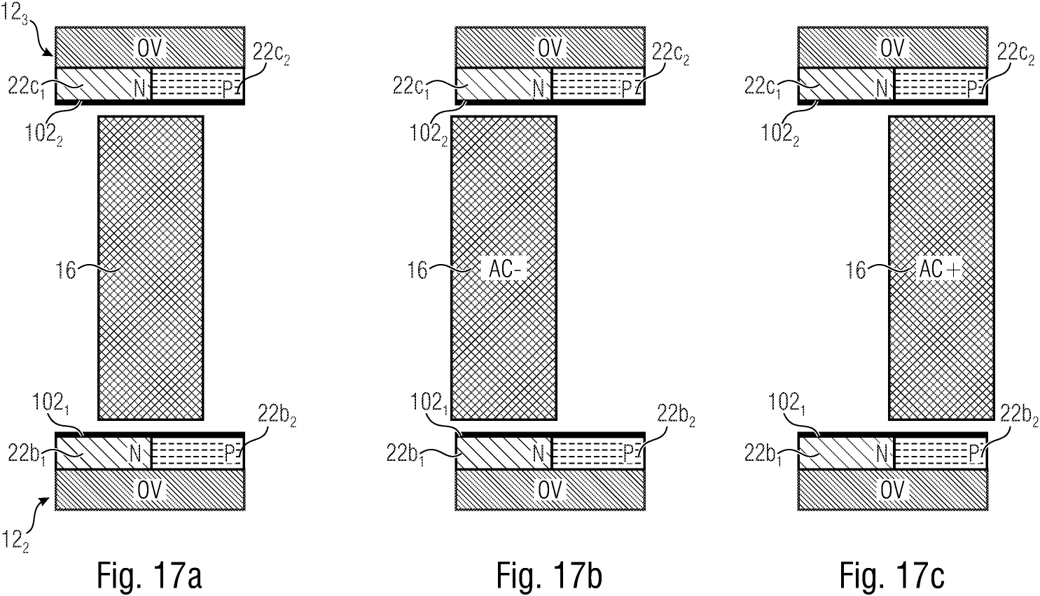

Referring to FIGS. 17a, 17b and 17c, a complementary condition is indicated in which n-doped regions 22c₁ and 22b₁ arranged on or integrated in layers 12₂ and 12₃, respectively, are arranged adjacent to p-doped regions 22c₂ and 22b₂, respectively. These may be covered by electrically insulating layers 102₁ and/or 102₂.

In this regard, the movable element 16 may be formed to be electrically conductive, for example, also via a corresponding doping. Based on applying a negative voltage AC- or a positive voltage AC+, a movement of the movable element 16 towards the n-doped regions 22c₁ and 22b₁ or towards the p-doped regions 22b₂ and 22c₁ can be triggered.

In other words, FIGS. 17a-c show an alternative drive to FIGS. 16a-c, based on the field effect, in which the doped layers are integrated in the cover wafer and the bottom wafer.

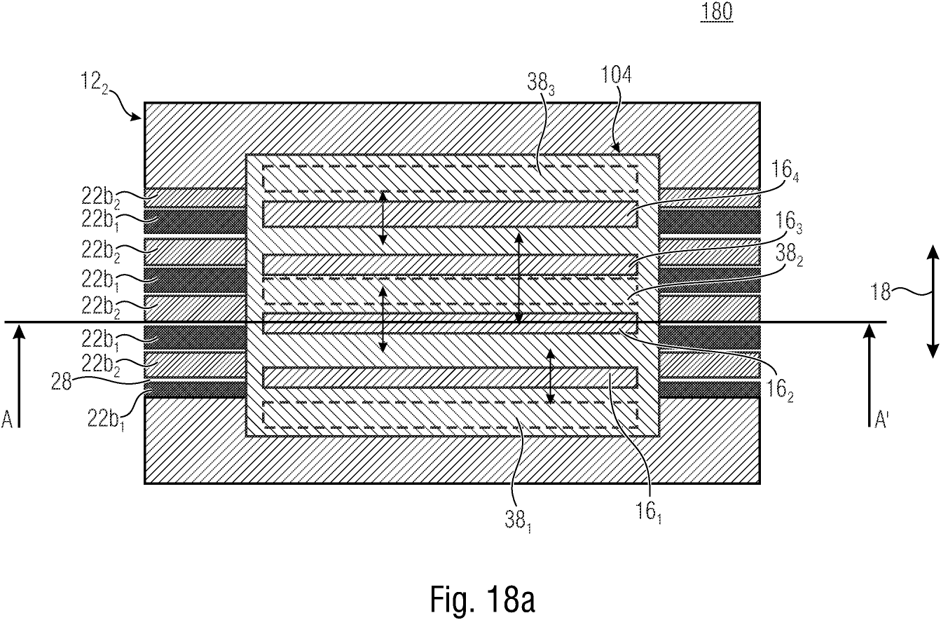

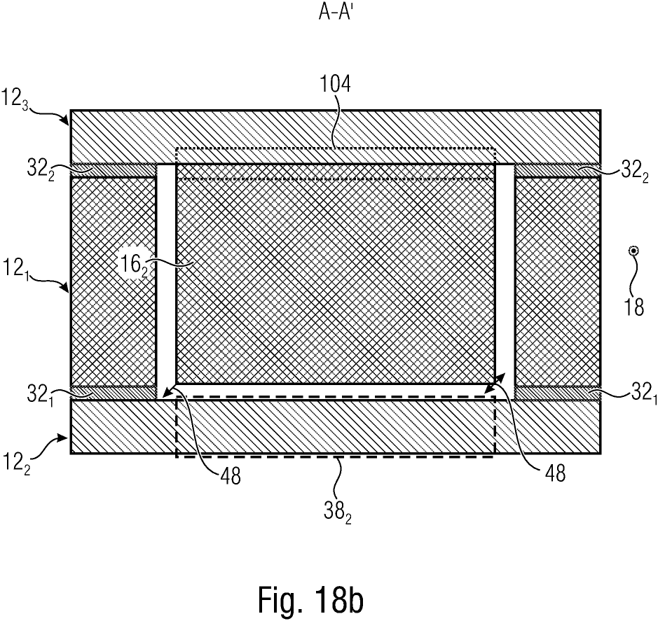

FIG. 18a shows a schematic top view of a MEMS device 180 according to an embodiment. In contrast to other embodiments described herein, the movable element is mechanically connected to the MEMS layer 12₃, which is not shown in FIG. 18a, via an elastic region. In this regard, the elastic region may comprise a layer arranged for this purpose, a remaining layer or a material specially provided for this purpose. The movable element is configured to perform a rotational movement or deformation of the elastic region based on the drive force.

For example, the elastic region may be provided in a region 104.

FIG. 18b shows a schematic side sectional view in the A-A′ plane of FIG. 18a. Due to the mechanical and elastic connection in the region 104, the movable element 16₂, like the other movable elements connected to the layer 12₃, can perform the movement adjacent to the layer 12₂, similar to a rocking movement or seesaw movement, so that a high amplitude of movement can be performed adjacent to the layer 12₂ and a low amplitude of movement can be performed in the region of the layer 12₃, but with high material expansion.

The advantage of such a configuration is that only two instead of three active slices/wafers are used and no additional layers need to be provided for this purpose, for example in the area of the cover 12₃.

As explained in connection with other embodiments, a driving unit may be implemented in a variety of ways, such as by providing electrodes on the layer 12₂ and/or the movable element 16₂ and/or by arranging, for example, doped regions. Electrodes on a side facing the layer 12₂, a face side, of the movable element 16₂ may be referred to as a face drive. Such a drive from the face side thus forms one implementation of the present invention. In other words, the fin, the movable element 16₂, may be driven from the fin face side by configuring the device wafer accordingly. For example, at least on the face side, the first drive structure may be arranged on a front side of the movable element. For example, electrodes may be arranged on or in the layer 12₁. For example, a positioning may be on a front side between the movable element 16₂ and the side of the layer 12₁, which is associated with the front sides of the movable elements. A height of the electrodes may be equal to or less than the height of the movable element.

In other words, FIGS. 18a and 18b show a top view and a side view of an alternative structure of a sound transducer. This differs significantly in the connection of the deflectable element to the cover wafer in a region 104. This connection is particularly advantageously made in a material-locking manner. 18 indicates the alternative direction of movement, perpendicular to the lateral extension of the resistive element. Here, the greatest deflection occurs in the region of the bottom wafer. The smallest deflection takes place in the region 104, the connecting region of the resistive element to the cover wafer. The connecting region 104 may have a stiffness that differs from the stiffness of the cover wafer and the resistive element, and is advantageously lower. In this case, the connection region 104 is a spring element. The resulting sub-cavities, which are separated from each other by the resistive elements, are connected to the surrounding fluid through openings in the bottom wafer and cover wafer (not shown).

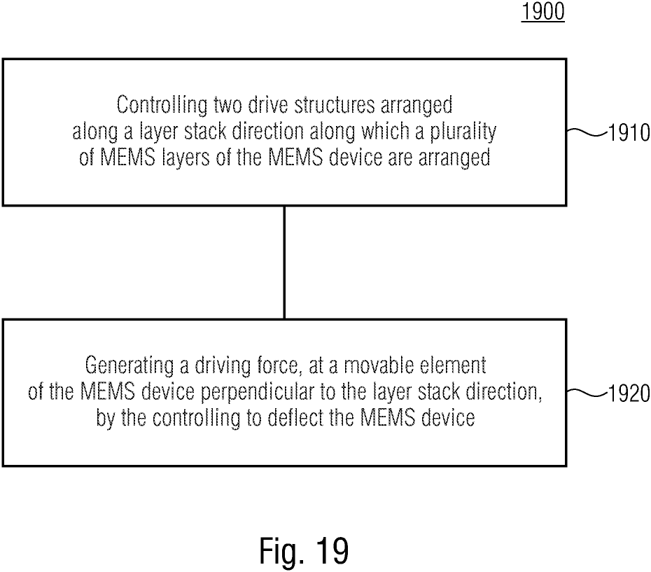

A method according to embodiments described herein is described with reference to a schematic flowchart in FIG. 19. Step 1910 of the method 1900 may include controlling two drive structures arranged along a layer stack direction along which a multitude of MEMS layers of the MEMS device are arranged. Step 1920 includes generating a drive force at a movable element of the MEMS device perpendicular to the layer stack direction through the controlling so as to deflect the MEMS device.

The method can be executed in such a way that, in the sense of a so-called “balanced” or linear control, two adjacent electrode elements of the driving unit, which are electrically insulated from one another by an electrode gap, a symmetrical and/or linear deflection of the movable element is controlled by controlling the electrode elements symmetrically about a reference potential, for example GND with respect to the applied potentials in the time average . Alternatively, the method may be performed asymmetrically or un-balanced or non-linearly by controlling the deflection of the movable element asymmetrically along an actuation direction with respect to an opposite direction in the time average. This may be obtained by different potential levels and/or different time intervals.

The embodiments described herein relate to microelectromechanical systems, MEMS, configured to have a large effective area for interaction with a fluid. In this regard, an increase in the effective area of deflectable displacement elements is a primary focus in some embodiments. The displacement elements, the movable elements 16, may be in contact with and interact directly or indirectly with a surrounding fluid. For example, micro-loudspeakers incorporating such a MEMS may generate a high sound pressure level relative to the surface area of the MEMS. Similarly, however, use as micropumps, ultrasonic transducers, or other MEMS-based applications are also possible for embodiments described herein, as they are connected by the task of moving a fluid.

Core aspects of the present invention are summarized again in other words below. In this regard, embodiments solve the problem of structuring limitation in existing etching processes, i.e., a limitation of geometric resolution, such as thinnest trenches to be etched, in volume-processing methods, such as electro-erosion, lithography, electroforming, nano-stamping, milling or other SI structuring, for the representation of field-driven driving effects, such as electrostatic or electromagnetic in-plane.

The “Bosch” Si structuring method limits the aspect ratio (depth to width) of etched Si structures to typically 30. In the current variations for micro loudspeakers, (NED, muscle, comb), the structuring of electrostatically deflectable elements (drive force) as well as the structuring of passive elements (resistive structures, displacement elements, fluidic resistive structures), which describe the fill factor of the chip area, is limited by the Bosch method. Drive force and fill factor are the main parameters to achieve a higher sound pressure level (SPL) per chip area (SPL/mm²) in micro loudspeakers. Therefore, new simpler drive versions have to be found which are not limited by the aspect ratio of the Bosch method and allow e.g. 100 dB/mm², or higher.

The solution of the invention is illustrated by the apparatus and method for deflecting one or more resistive elements in Chapter 6 of this description of the invention. The solution includes an apparatus comprising a MEMS sound transducer as a layer system. The core of the invention is:
Increase in the drive force: The drive force of the new drive is no longer limited by the aspect ratio of the Bosch method. The basic idea is the execution of the electrode gap by the bonding process of at least two discs. The active electrode gap can thus be set to be particularly small, independent of limitations of the Bosch process, and thus a large force can be generated. This gap is generated between one disc to be bonded and the other. The actively moving element (e.g. a beam structure) in the first disc to be bonded (device wafer) is then spaced apart from the other disc to be bonded (cover or bottom wafer) by the gap. The drive is thus generated by the gap along the circumference or parts of the circumference of the actively movable element.
In one implementation (“cover drive”), the force is defined by the vertical distance from the cover or bottom wafer top to the top of the device wafer. The distance between the cover wafer and the device wafer can be defined independently of the Bosch method and thus larger aspect ratios or larger drive forces can be achieved with the cover drive. Here, the drive takes place along the longitudinal edges at the top and or bottom of the actively movable element (as the upper lower part of the circumference) as the closest electrode side to the cover and or bottom.
In one implementation (“face drive”), the force between the actively movable element (e.g. elongated flap element) and the cover or bottom is determined by the lateral distance between the two bonded discs. The two discs will at least partially engage with each other. Consequently, the drive takes place along face sides (lateral part of the circumference of the actively movable structures). Advantageously, additional conductive layers can be omitted here compared to the cover drive.
Several devices can be stacked together, i.e. all discs have actively deflectable elements.
Increase in the fill factor: The fill factor of a micro loudspeaker, for example, is characterized by the maximum between the fill factor of the actuator and the fill factor of the resistive structures in the displacement plane (device plane). If the fill factors of both components of the micro loudspeaker are limited, e.g. by the Bosch method, then it is difficult to increase the fill factor of the micro loudspeaker arbitrarily. Therefore, it is important to make the fill factor of the actuator as well as the resistive structures independent of the Bosch method. In the cover drive, the fill factor of the actuator as well as the resistive structures level are independent of the Bosch method.

Compared to the known technology, the cover drive can be characterized, for example, in that an electrically conductive layer is arranged between a cover wafer and the layer containing fluidic resistive elements. Similarly, another electrically conductive layer is arranged between the same layer containing resistive elements, and a bottom wafer.

Resistive element, as used herein, does not refer to an electrical resistor, but a resistive element that interacts with a surrounding fluid, such as the movable element 16. In other words, this resistive element may also be referred to as a displacement element, a fin, or an active or passive actuator.

The first and second electrical layers can be structured so that one or more separate electrical voltages can be applied within the two electrical layers. If only one voltage (per cover/bottom wafer) is used (depending on the application), the cover or bottom wafers themselves can be used as the first and second electrical layers.

If two or more voltages (per cover/bottom wafer) are used (depending on the application), the following applies:

The first and second electrically conductive layers are mechanically firmly connected to the layers of the top or bottom wafer via an insulating connecting layer. The main sides of these electrically conductive layers face away from the respective adjacent layers of the top and bottom wafers and face each other. Between both main sides of the electrically conductive layers, a further layer is arranged from which a cavity is formed by SI structuring methods. This cavity surrounds at least one resistive element with respect to the plane of the layer arranged parallel to the layer of the cover and handling wafers. Comparable to the cavity itself, a resistive element is formed out of a doped semiconductor material by SI structuring methods and subdivides the cavity into sub-cavities.

With the cover drive, both linear operation and non-linear operation can be realized. Wherein the embodiments with linear deflection behavior and non-linear deflection behavior differ from each other. Advantageous embodiments are drives with linear deflection behavior.

In other words, the cover drive can be used to implement both a “balanced actuator” (linear actuator) and a “non-balanced actuator”.

The following is meant by “balanced actuator” linear operation/ linear deflection method/ linear deflection behavior:
When an electrical voltage is applied to the first and second conductive layers, electrical forces are created between the conductive layers and the resistive elements. When the voltage on all conductive layers is equal, there is an equilibrium between the electrical forces and the resistive element does not move.
However, if the voltage within the first or second conductive layers is not equal (voltage 1 and voltage 2), then an imbalance occurs and the resistive element moves linearly in one direction or the other. If voltage 1 and voltage 2 change in opposite phase (one increases and the other decreases), then two electrical forces 1 and 2 act on each resistive element in opposite directions and accordingly one force increases and the other decreases. The resulting force (F1+F2) is linearly dependent on the applied voltages 1 and 2, which means that the movement of the resistive element is also linearly dependent on the voltage. The linearity between the applied electrical signal and the deflection of the resistive element has an influence on the sound of a loudspeaker. The more linear the relationship, the lower the distortion factor. The more linear the relationship, the better the sound can be reproduced by the loudspeaker.

The following is meant by “non-balanced actuator” non-linear operation/non-linear deflection method:
Only one force (not two) acts on the resistive elements in a certain direction. This force depends quadratically on the voltage, or the movement of resistive element depends quadratically on the voltage. I.e. there is no linear dependence between voltage and movement of the resistive element. Accordingly, the quality of the sound suffers. In other words, the distortion factor of the loudspeaker is significantly higher compared to a loudspeaker with a linearly driven sound transducer.
A “non-balanced actuator” (non-linear operation/non-linear deflection method) is usually easier to implement technologically because only one voltage needs to be applied to the conductive layers (not two or more). That is, the conductive layers do not need to be structured. In one embodiment, the conductive layers could even be completely omitted, so that the used voltage can be applied directly on the cover or bottom wafer. In this case, the top and bottom wafers can be structured, see FIGS. 8a-c.

Advantageously, the dense packing enabled in the core idea of the invention can be combined with a microresonator structure so that sound radiation in the low frequency range is improved.

In other words, the electrodes and all corresponding sub-elements are formed in one or more layers. Electrical insulation of the sub-electrodes is provided by a spacer 28 which may comprise, for example, oxide or nitride, for example Si₂O, Si₃N₄ or AL₂O₃.

A method of controlling and deflecting the resistive elements, and thus interacting with the surrounding fluid, may be the same between the different movable elements, suspended from one wafer or exposed from both wafers.

Advantages of cover drives described herein are that

1. the force of the actuator can be controlled by the gap between the movable element and the bottom wafer or cover wafer during bonding between the wafers, but is not determined by an etching method, for example. This eliminates the limitation of, for example, the Bosch method to an aspect ratio of in the order of 30. That is, the actuator can be manufactured with an aspect ratio greater than 30.

2. Furthermore, the use of BSOI wafers can be dispensed with. For the cover wafer or the bottom wafer as well as for the device wafer, the layer 12₁, standardized Si wafers can be used, which are much cheaper.

3. In addition, contrasts to classical NED (Nanoscopic Electrostatic Drive) or comb drives, a BSOI wafer can be used, which conventionally cannot be machined from two sides to increase the aspect ratio. When fabricating a cover drive described herein, both BSOI wafers and wafers can be machined from both sides so that the trenches between the resistive structures fabricated by the Bosch method can have a double aspect ratio, for example, of 2×30, i.e., approximately 60. When multiple device wafers are bonded together, the aspect ratio can be further increased, as described, for example, in connection with FIGS. 15b and 15c. For example, an aspect ratio of 120 (two device wafers), 180 (three device wafers), 240 (four device wafers), etc. may be obtained.

4. Since the fill factor of the actuator (see first advantage) as well as the device level (see previous advantage) can be independent of methods such as the Bosch method, the fill factor of the overall system, i.e. the number of actuators or resistive structures/area unit can be greatly improved.
a) Because parts of the actuator, namely the electrode gap, are decoupled from the device plane (core idea of the invention), the mechanical and movable elements in the device plane can be packed more densely and thus the fill factor of the overall system (number of actuators or resistive structures/area unit) can be advantageously greatly improved (more sound per area).
b) Furthermore, the symmetrical system with respect to half the device height can be stacked and thus the apparent aspect ratio can theoretically be increased without limit. The basis for this is the non-existence of any support layers or similar relative to the device plane.

5. Simple technology for device as well as cover/bottom wafers: filled HR trenches are not available to realize insulations on the chip (HR = High Aspect Ratio). No short circuits are expected within one plane (between resistive element and cover and bottom wafers). This significantly increases the yield of chips that can be diced from a wafer without short circuits.

6. The final device of an embodiment consists only of Si and SiO₂. No AL₂O₃ layers or other layers are necessary, which can induce stress in the system, for example.

7. The resistive structure is driven from both sides (top and bottom). The actuator is symmetrically present from both sides (top and bottom) and over the whole length of the resistive structure. The resistive structures do not wobble compared to the case where the resistive structures are driven from one side only.

8. No electric field between the resistive structures: device wafer has the same potential everywhere -> no filter effect.

9. Direct bonding Si—SiO₂ or SiO₂—SiO₂ is possible at 1000° C.: 25-50 wafers can be bonded simultaneously in one furnace. This results in cost savings in the manufacturing process
a. Avoiding a lateral pull-in between resistive structures is possible: all resistive structures have the same potential.

Although some aspects have been described in relation to an apparatus, it is understood that these aspects also represent a description of the corresponding method, so that a block or component of an apparatus is also to be understood as a corresponding method step or as a feature of a method step. Similarly, aspects described in connection with or as a method step also represent a description of a corresponding block or detail or feature of a corresponding apparatus.

Depending on particular implementation requirements, embodiments of the invention may be implemented in hardware or in software. The implementation may be carried out using a digital storage medium, for example, a floppy disk, a DVD, a Blu-ray disc, a CD, a ROM, a PROM, an EPROM, an EEPROM or a FLASH memory, a hard disk or any other magnetic or optical storage medium on which electronically readable control signals are stored, which are able to interact or interact with a programmable computer system in such a way as to carry out the respective method. Therefore, the digital storage medium may be computer-readable. Thus, some embodiments according to the invention comprise a data carrier having electronically readable control signals capable of interacting with a programmable computer system such that any of the methods described herein is performed.

Generally, embodiments of the present invention may be implemented as a computer program product having program code, the program code being operative to perform any of the methods when the computer program product runs on a computer. For example, the program code may also be stored on a machine-readable medium.

Other embodiments include the computer program for performing any of the methods described herein, wherein the computer program is stored on a machine-readable medium.

In other words, an embodiment of the method according to the invention is thus a computer program comprising program code for performing any of the methods described herein when the computer program runs on a computer. Thus, another embodiment of the methods according to the invention is a data carrier (or a digital storage medium or a computer-readable medium) on which the computer program for performing any of the methods described herein is recorded.

Thus, a further embodiment of the method according to the invention is a data stream or sequence of signals constituting the computer program for performing any of the methods described herein. The data stream or sequence of signals may, for example, be configured to be transferred over a data communication link, for example over the Internet.

Another embodiment comprises processing means, such as a computer or programmable logic device, configured or adapted to perform any of the methods described herein.

Another embodiment includes a computer having installed thereon the computer program for performing any of the methods described herein.

In some embodiments, a programmable logic device (for example, a field-programmable gate array, FPGA) may be used to perform some or all of the functionalities of the methods described herein. In some embodiments, a field-programmable gate array may interact with a microprocessor to perform any of the methods described herein. Generally, in some embodiments, the methods are performed on the part of any hardware device. This may be general-purpose hardware, such as a computer processor (CPU), or hardware specific to the method, such as an ASIC.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A MEMS device comprising:
a layer stack comprising a plurality of MEMS layers arranged along a layer stack direction;
a movable element formed in a first MEMS layer; the moveable element arranged between a second MEMS layer and a third MEMS layer of the layer stack; and
a driving unit comprising a first drive structure mechanically firmly connected to the movable element and a second drive structure mechanically firmly connected to the second MEMS layer;
wherein the driving unit is configured to generate on the movable element a drive force perpendicular to the layer stack direction, and the drive force is configured to deflect the movable element.

2. The MEMS device according to claim 1, wherein the first drive structure and the second drive structure are spaced apart by a gap and arranged opposite to each other; wherein a dimension of the gap along the layer stack direction is adjusted by a bonding process.

3. The MEMS device according to claim 1, wherein the movable element comprises a plurality of layers bonded by a bonding process.

4. The MEMS device according to claim 1, wherein the second drive structure is a structured electrode structure comprising at least one first electrode element and one second electrode element electrically insulated therefrom; the MEMS device being configured to apply a first electrical potential to the first electrode element and a different second electrical potential to the second electrode element; wherein the MEMS device is further configured to apply a third electrical potential to the first drive structure to generate the drive force in cooperation of the third electrical potential and the first electrical potential or the second electrical potential.

5. The MEMS device according to claim 4, wherein the first electrode element and the second electrode element are electrically insulated from each other by an electrode gap, wherein a rest position of the movable element is arranged symmetrically and/or asymmetrically opposite the electrode gap.

6. The MEMS device according to claim 4, wherein the movable element comprises a single third potential.

7. The MEMS device according to claim 1,
wherein the movable element is polygonal, curved once or curved multiple times in a cross-section; or
wherein the movable element comprises, in a cross-section along the layer stack direction, a variable dimension perpendicular to the layer stack direction.

8. The MEMS device according to claim 1, wherein, along an axial path perpendicular to the layer stack direction, electrodes of the second drive structure comprise a constant or a variable lateral dimension perpendicular to the axial direction.

9. The MEMS device according to claim 1, wherein the driving unit comprises a third drive structure mechanically firmly connected to the third MEMS layer, wherein a first gap is arranged between the first drive structure and the second drive structure, and a second gap is arranged between the first drive structure and the third drive structure;
wherein the driving unit is configured to provide the drive force based on a first interaction between the first drive structure and the second drive structure and a second interaction between the first drive structure and the third drive structure.

10. The MEMS device according to claim 9, wherein the driving unit is configured to generate a first drive force component based on the first interaction and a second drive force component based on the second interaction, the MEMS device being configured to generate the first drive force component and the second drive force component in-phase or with a phase shift.

11. The MEMS device according to claim 1, wherein the movable element is mechanically connected to the third MEMS layer via an elastic region; wherein the movable element is configured to perform a rotational movement based on the drive force while deforming the elastic region.

12. The MEMS device according to claim 11, wherein, on a face side, the first drive structure is arranged on a face side of the movable element.

13. The MEMS device according to claim 1, wherein an electrode structure is arranged on a side facing the second MEMS layer and/or facing the third MEMS layer, and forms at least a part of the first drive structure.

14. The MEMS device according to claim 1, wherein the movable element comprises a surface structuring on a side facing the second MEMS layer and/or the second MEMS layer comprises a surface structuring on a side facing the movable element to locally change a distance between the movable element and the second MEMS layer.

15. The MEMS device according to claim 1, wherein electrodes of the first drive structure and/or electrodes of the second drive structure are arranged and interconnected in an interdigital manner.

16. The MEMS device according to claim 1, comprising a multitude of movable elements arranged side by side in a common MEMS plane and coupled to each other fluidically or by means of a coupling element.

17. The MEMS device according to claim 16, wherein a drive structure comprising at least two connected electrodes arranged side by side is arranged on each of the movable elements, one electrode of which is connected to a first electrical potential and a second electrode of which is connected to a second, different electrical potential; wherein facing electrodes of adjacent movable elements are connected to a combination of the first electrical potential and the second electrical potential.

18. The MEMS device according to claim 1, wherein the movable element is movably arranged in a MEMS cavity, wherein by means of a movement of the movable element, at least a sub-cavity of the cavity is alternately enlarged and diminished in size, wherein the sub-cavity locally extends into the second MEMS layer.

19. The MEMS device according to claim 1, wherein the movable element comprises an element length along an axial extension direction perpendicular to the layer stack direction, wherein an electrode of the first drive structure comprises a plurality of electrode segments along the element length, adjacent electrode segments being electrically connected to each other by electrical conductors, the electrical conductors comprising a lower mechanical stiffness than the electrode segments along a direction perpendicular to the element length.

20. The MEMS device according to claim 1, wherein the movable element is configured to provide an interaction with a fluid.

21. The MEMS device according to claim 1, wherein the driving unit comprises a fourth drive structure arranged on a side of the second MEMS layer facing away from the movable element, a further movable element being arranged adjacent to the fourth drive structure and forming a stacked arrangement with the movable element.

22. A method of operating a MEMS device, comprising:
controlling two drive structures arranged along a layer stack direction along which a multitude of MEMS layers of the MEMS device are arranged, and
generating a drive force at a movable element of the MEMS device perpendicular to the layer stack direction through the controlling so as to deflect the MEMS device.

23. The method according to claim 22, wherein a symmetrical and/or linear deflection of the movable element is controlled by means of a MEMS device of two adjacent electrode elements which are electrically insulated from one another by an electrode gap, by controlling an electrode element symmetrically with respect to the applied potentials in the time average.

24. The method according to claim 22, wherein the deflection of the movable element is controlled asymmetrically in the time average along an actuation direction with respect to an opposite direction.
